(19) United States
(12) Patent Application Publication
(10) Pub. No.: US 2026/0333828 A1
(43) Pub. Date: Oct. 22, 2026

(54) TRANSISTOR DEVICE WITH GAS-BLOCKING LAYERS

(71) Applicant: Taiwan Semiconductor Manufacturing Company, Ltd., Hsinchu (TW)

(72) Inventors: Wu-Wei Tsai, Taoyuan City (TW); Yu-Ming Hsiang, New Taipei City (TW); Kuan-Chi Wang, Hsinchu (TW); Hai-Ching Chen, Hsinchu City (TW)

(21) Appl. No.: 19/721,269

(22) Filed: Jun. 26, 2026

Related U.S. Application Data
(63) Continuation of application No. 18/661,823, filed on May 13, 2024.

(51) Int. Cl. H10D 64/68; H10D 84/40; H10W 42/00

(52) U.S. Cl. CPC H10D 64/691; H10D 84/401; H10W 42/00

(57) ABSTRACT

An integrated chip includes an active layer. A first source/drain electrode and a second source/drain electrode are on an upper surface of the active layer. A gate electrode is on a first side of the active layer and between the first source/drain electrode and the second source/drain electrode. A gate dielectric layer is between the gate electrode and the active layer. A first blocking layer is on a second side of the active layer, opposite the first side of the active layer, and spaced from the active layer. A second blocking layer is on the first side of the active layer, spaced from the active layer, and extends along the gate electrode.

### REFERENCE TO RELATED APPLICATION

This Application is a Continuation of U.S. application Ser. No. 18/661,823, filed on May 13, 2024, the contents of which are hereby incorporated by reference in their entirety.

### BACKGROUND

Many electronic devices contain a multitude of metal oxide semiconductor field-effect transistors (MOSFETs). A MOSFET includes a gate arranged between a source and a drain. MOSFETs may be categorized as high voltage (HV), medium voltage (MV) or low voltage (LV) devices, depending on the magnitude of the voltage applied to the gate to turn the MOSFET on. The structural design parameters of each MOSFET in an electronic device vary depending on the desired electrical properties.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of a transistor device comprising blocking layers surrounding an active layer.

FIGS. 2, 4, 6, 8, 10 illustrate cross-sectional views of various embodiments of the transistor device of FIG. 1 in which a gate electrode is over the active layer.

FIGS. 3, 5, 7, 9, 11 illustrate top views of some embodiments of the transistor devices of FIGS. 2, 4, 6, 8, 10, respectively.

FIG. 12 illustrates a cross-sectional view of some embodiments of an integrated chip including the transistor device of FIG. 10 disposed within an interconnect structure over a substrate.

FIG. 13 illustrates a cross-sectional view of some embodiments of the transistor device of FIG. 1 in which the gate electrode is under the active layer.

FIG. 14 illustrates a cross-sectional view of some embodiments of an integrated chip including the transistor device of FIG. 13 disposed within an interconnect structure over a substrate.

FIG. 15 illustrates a cross-sectional view of some embodiments of the transistor device of FIG. 1 in which the transistor device is disposed along a substrate.

FIG. 16 illustrates a cross-sectional view of some embodiments of an integrated chip including the transistor device of FIG. 15.

FIGS. 17-22, FIGS. 23-29, FIGS. 30-33, FIGS. 34-37, and FIGS. 38-41 illustrate cross-sectional views of various embodiments of methods for forming a transistor device comprising a gate electrode over an active layer and blocking layers surrounding the active layer.

FIG. 42 illustrates a flow diagram of some embodiments of a method for forming a transistor device comprising a gate electrode over an active layer and blocking layers surrounding the active layer.

FIGS. 43-47 illustrate cross-sectional views of some embodiments of a method for forming a transistor device comprising a gate electrode under an active layer and blocking layers surrounding the active layer.

FIG. 48 illustrates a flow diagram of some embodiments of a method for forming a transistor device comprising a gate electrode under an active layer and blocking layers surrounding the active layer.

FIGS. 49-53 illustrate cross-sectional views of some other embodiments of a method for forming a transistor device along a substrate, the transistor device comprising blocking layers surrounding an active layer of the substrate.

FIG. 54 illustrates a flow diagram of some embodiments of a method for forming a transistor device along a substrate, the transistor device comprising blocking layers surrounding an active layer of the substrate.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An integrated chip includes a transistor device. The transistor device includes a first source/drain electrode and a second source/drain electrode along an active layer, a gate electrode between the first source/drain electrode and the second source/drain electrode, and a gate dielectric layer between the gate electrode and the active layer. A channel region of the active layer extends from the first source/drain electrode to the second source/drain electrode.

In some cases, processes performed during fabrication (e.g., material deposition processes and/or etching processes) can negatively affect the active layer of the transistor device. For example, process gases used during fabrication may penetrate into the active layer. In some cases, this penetration of process gas particles into the active layer may alter the charge carrier concentration in the channel region of the active layer. Altering the carrier concentration in the channel region of the active layer may negatively affect the operation the transistor device and/or may reduce the reliability of the transistor device.

In various embodiments of the present disclosure, blocking layers surround the active layer to block process gasses from reaching the active layer. For example, a first blocking layer is under the active layer and a second blocking layer is over the active layer. The blocking layers can block process gas particles from reaching the active layer. By blocking process gas atoms from reaching the active layer, the stability of the carrier concentration in the channel region of the active layer can be improved. As a result, the operation the transistor device and/or the reliability of the transistor device may be improved.

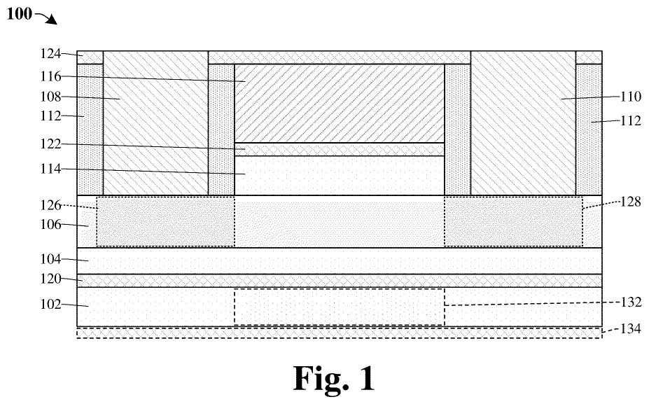

FIG. 1 illustrates a cross-sectional view 100 of some embodiments of a transistor device comprising blocking layers surrounding an active layer 106.

A second dielectric layer 104 is over a first dielectric layer 102. An active layer 106 is over the second dielectric layer 104. A third dielectric layer 112 is over the active layer 106. A first source/drain electrode 108 and a second source/drain electrode 110 extend through the third dielectric layer 112 to the active layer 106. In some embodiments, the active layer 106 comprises silicon, amorphous silicon, polysilicon, copper oxide, tin oxide, indium oxide, indium zinc oxide (IZO), indium gallium oxide (IGO), indium gallium zinc oxide (IGZO), indium tungsten oxide (IWO), indium tungsten zinc oxide (IWZO), or some other suitable material.

A gate electrode 116 is on a first side of the active layer 106 (e.g., over the active layer 106). A gate dielectric layer 114 is directly between the gate electrode 116 and the active layer 106. The gate electrode 116 and the gate dielectric layer 114 are directly between the first source/drain electrode 108 and the second source/drain electrode 110. In some embodiments, a channel region (not labeled) of the active layer 106 extends from the first source/drain electrode 108 to the second source/drain electrode 110.

The transistor device includes a blocking layer 120 on a second side of the active layer 106 (e.g., under the active layer 106). For example, blocking layer 120 is directly between the first dielectric layer 102 and the second dielectric layer 104. The transistor device includes another blocking layer (e.g., blocking layer 122 and/or blocking layer 124) on the first side of the active layer 106 (e.g., over the active layer 106). For example, in some embodiments, the transistor device includes blocking layer 122 on a first side of the gate electrode 116 (e.g., under the gate electrode 116) and directly between the gate electrode 116 and the gate dielectric layer 114. In some other embodiments, the transistor device alternatively includes blocking layer 124 on a second side of the gate electrode 116 (e.g., over the gate electrode 116). In some other embodiments, the transistor device includes both blocking layer 122 and blocking layer 124.

The blocking layers 120, 122, 124 can block process gas atoms from reaching the active layer 106. Thus, the stability of the carrier concentration in the channel region (not labeled) of the active layer 106 may be improved. As a result, the operation the transistor device and/or the reliability of the transistor device may be improved.

In some embodiments, the active layer 106 comprises a semiconductor (e.g., silicon or some other suitable material), and the transistor device includes a first source/drain region 126 and a second source/drain region 128 in the active layer 106 directly under the first source/drain electrode 108 and the second source/drain electrode 110, respectively. Source/drain region(s) may refer to a source or a drain, individually or collectively dependent upon the context. The source/drain regions 126, 128 are doped regions of the active layer 106, where the source/drain regions 126, 128 have a first doping type (e.g., n type or p type) and the active layer 106 has a second doping type (e.g., p type or n type) different from the first doping type. In such embodiments, the channel region (not labeled) of the active layer 106 extends from the first source/drain region 126 to the second source/drain region 128.

In some embodiments, the transistor device alternatively includes a gate electrode 132 (shown in “phantom” with dashed lines) on the second side of the active layer 106 (e.g., under the active layer 106) and is devoid of gate electrode 116. Gate electrode 132 is between sidewalls of the first dielectric layer 102. The second dielectric layer 104 forms a gate dielectric layer between gate electrode 132 and the active layer 106. The third dielectric layer 112 extends between the source/drain electrodes 108, 110 (e.g., in place of gate electrode 116). Blocking layer 124 is on the first side of the active layer 106 (e.g., over the active layer 106) and extends along the third dielectric layer 112. The transistor device includes another blocking layer (e.g., blocking layer 120 and/or blocking layer 134) on the second side of the active layer 106 (e.g., under the active layer 106). For example, in some embodiments, the transistor device includes blocking layer 120 on a first side of gate electrode 132 and directly between gate electrode 132 and the second dielectric layer 104 (e.g., the gate dielectric layer). In some other embodiments, the transistor device includes blocking layer 134 on the second side of gate electrode 132. In some other embodiments, the transistor device includes both blocking layer 120 and blocking layer 134.

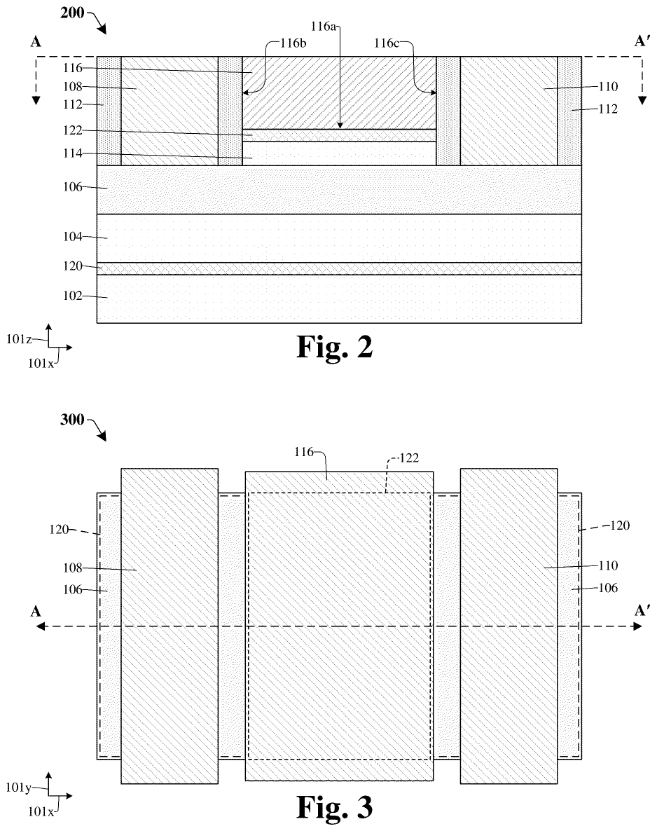

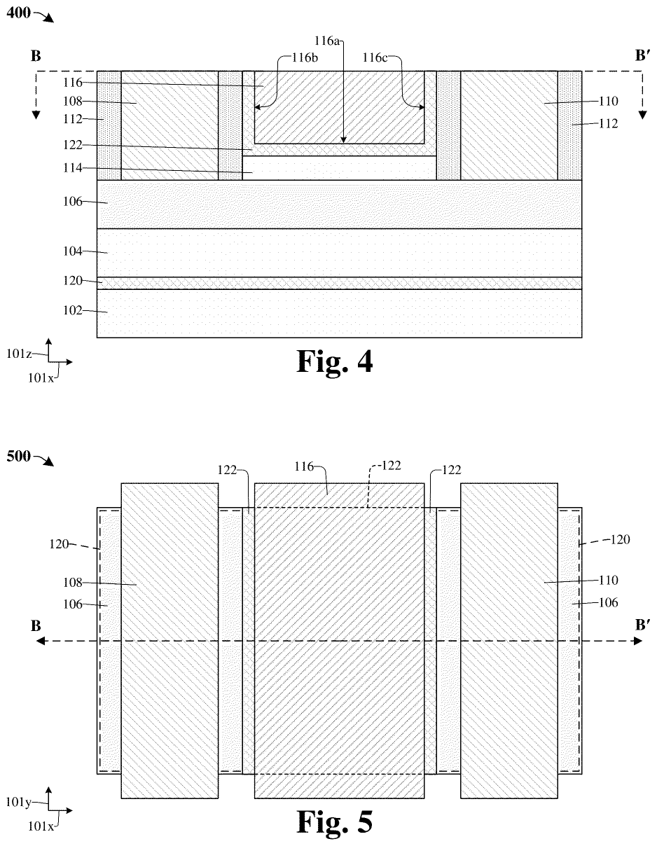

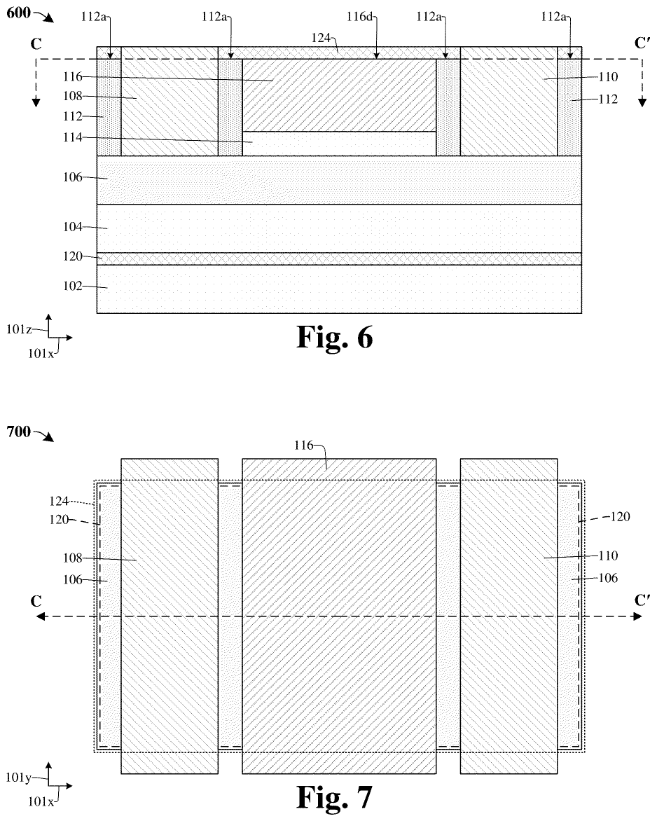

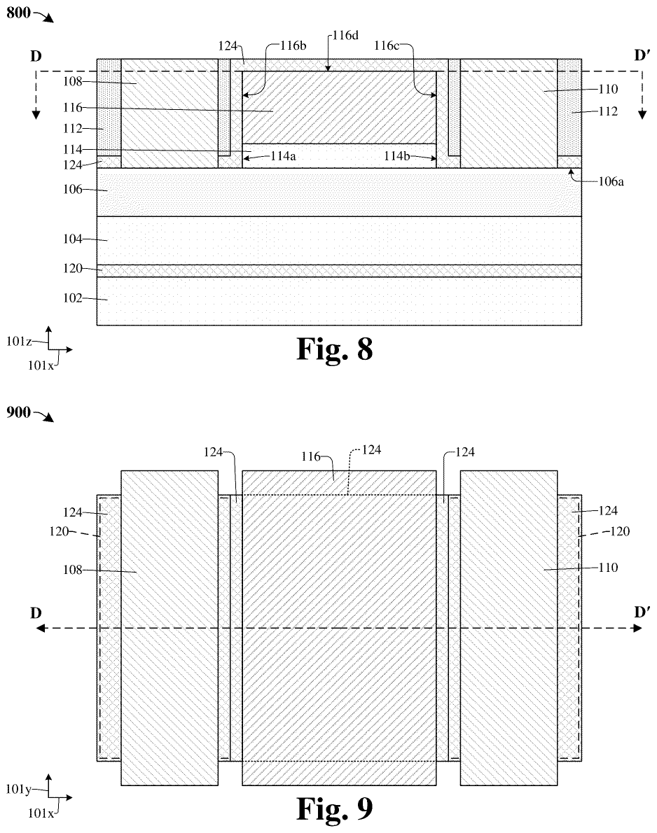

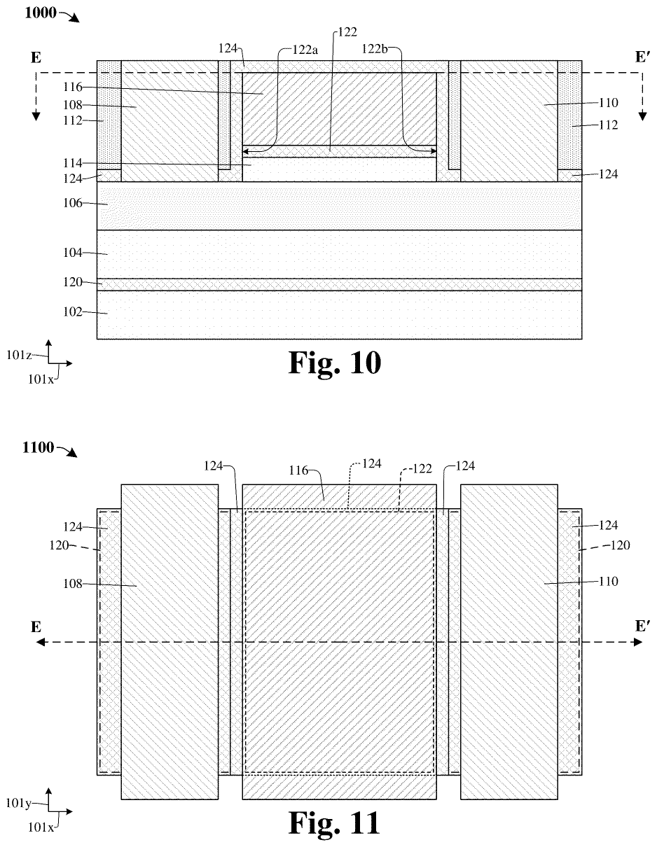

FIGS. 2, 4, 6, 8, 10 illustrate respective cross-sectional views 200, 400, 600, 800, 1000 of various embodiments of the transistor device of FIG. 1 in which the gate electrode 116 is over the active layer 106. FIGS. 3, 5, 7, 9, 11 illustrate respective top views 300, 500, 700, 900, 1100 of some embodiments of the transistor devices of FIGS. 2, 4, 6, 8, 10, respectively. In some embodiments, cross-sectional view 200 of FIG. 2 may be taken across line A-A′ of FIG. 3, cross-sectional view 400 of FIG. 4 may be taken across line B-B′ of FIG. 5, cross-sectional view 600 of FIG. 6 may be taken across line C-C′ of FIG. 7, cross-sectional view 800 of FIG. 8 may be taken across line D-D′ of FIG. 9, and cross-sectional view 1000 of FIG. 10 may be taken across line E-E′ of FIG. 11. The third dielectric layer 112 is not shown in FIGS. 3, 5, 7, 9, 11 for clarity of illustration of underlying layers. Blocking layer 120 is shown in “phantom” (e.g., by dashed lines) in FIGS. 3, 5, 7, 9, 11.

In the embodiments illustrated in FIGS. 2-11, blocking layer 120 is between the first dielectric layer 102 and the second dielectric layer 104. Blocking layer 120 is vertically spaced (e.g., along direction 101z) from the active layer 106. Blocking layer 120 has a width (e.g., along direction 101x) and a length (e.g., along direction 101y) similar to the width and length of the active layer 106. The source/drain electrodes 108, 110 and the gate electrode 116 are elongated along direction 101y.

In some embodiments (e.g., as illustrated in cross-sectional view 200 of FIG. 2 and corresponding top view 300 of FIG. 3), the transistor device includes blocking layer 122 directly between the gate electrode 116 and the gate dielectric layer 114. The blocking layer 122 extends laterally (e.g., along direction 101x) along a bottom surface 116a of the gate electrode 116 from a first sidewall 116b to a second sidewall 116c of the gate electrode 116. The third dielectric layer 112 extends along the sidewalls 116b, 116c of the gate electrode 116, sidewalls of blocking layer 122, and sidewalls of the gate dielectric layer 114. Blocking layer 122 is vertically spaced (e.g., along direction 101z) from the active layer 106. Blocking layer 122 has a width (e.g., along direction 101x) similar to the width of the gate electrode 116. Blocking layer 122 has a length (e.g., along direction 101y) similar to the length of the active layer 106. Blocking layer 122 is shown in “phantom” in FIG. 3.

In some embodiments (e.g., as illustrated in cross-sectional view 400 of FIG. 4 and corresponding top view 500 of FIG. 5), blocking layer 122 extends laterally (e.g., along direction 101x) along a bottom surface 116a of the gate electrode 116 and vertically (e.g., along direction 101z) along the first sidewall 116b and the second sidewall 116c of the gate electrode 116 (directly between the gate electrode 116 and the third dielectric layer 112). A portion of blocking layer 122 is shown in “phantom” in FIG. 5.

In some embodiments (e.g., as illustrated in cross-sectional view 600 of FIG. 6 and corresponding top view 700 of FIG. 7), the transistor device includes blocking layer 124 over the gate electrode 116. Blocking layer 124 extends laterally (e.g., along direction 101x) along a top surface 116d of the gate electrode 116 and along top surfaces 112a of the third dielectric layer 112. The source/drain electrodes 108, 110 extend through blocking layer 124. The transistor device is devoid of blocking layer 122 so that the gate electrode 116 directly contacts the gate dielectric layer 114. Blocking layer 124 has a width (e.g., along direction 101x) and a length (e.g., along direction 101y) similar to the width and length of the active layer 106. Blocking layer 124 is shown in “phantom” in FIG. 7.

In some embodiments (e.g., as illustrated in cross-sectional view 800 of FIG. 8 and corresponding top view 900 of FIG. 9), blocking layer 124 extends laterally along the top surface 116d of the gate electrode 116, vertically along sidewalls 116b, 116c of the gate electrode 116 (directly between the gate electrode 116 and the third dielectric layer 112), vertically along sidewalls 114a, 114b of the gate dielectric layer 114 (directly between the gate dielectric layer 114 and the third dielectric layer 112), and laterally along the top surface 106a of the active layer 106 (directly between the third dielectric layer 112 and the active layer 106). The source/drain electrodes 108, 110 extend through blocking layer 124 to the active layer 106. A portion of blocking layer 124 is shown in “phantom” in FIG. 9.

In some embodiments (e.g., as illustrated in cross-sectional view 1000 of FIG. 10 and corresponding top view 1100 of FIG. 11), the transistor device includes both blocking layer 122 and blocking layer 124. Blocking layer 124 extends along sidewalls 122a, 122b of blocking layer 122. Blocking layer 122 and a portion of blocking layer 124 are shown in “phantom” in FIG. 11.

In the embodiments illustrated in FIGS. 2-11, blocking layer 122 comprises a different material(s) than blocking layer 120 and blocking layer 124. For example, in some embodiments, blocking layer 120 comprises a first oxide, blocking layer 124 comprises a second oxide, and blocking layer 122 comprises a third oxide different than the first oxide and the second oxide. In some embodiments, blocking layer 122 comprises indium oxide, indium tin oxide, indium zinc oxide, or some other suitable material. In some embodiments, blocking layer 120 and/or blocking layer 124 comprise any of silicon nitride, aluminum oxide, hafnium aluminum oxide, zirconium aluminum oxide, or some other suitable material. In some embodiments, blocking layer 120, blocking layer 122, and blocking layer 124 have thicknesses (e.g., along direction 101z) which range from about 1 nanometer to about 10 nanometers, about 2 nanometers to about 9 nanometers, less than 10 nanometers, or some other suitable range.

In some embodiments, the active layer 106 comprises silicon, amorphous silicon, polysilicon, copper oxide, tin oxide, indium oxide, indium zinc oxide (IZO), indium gallium oxide (IGO), indium gallium zinc oxide (IGZO), indium tungsten oxide (IWO), indium tungsten zinc oxide (IWZO), or some other suitable material and has a thickness (e.g., along direction 101z) which ranges from about 1 nanometer to about 10 nanometers, about 2 nanometers to about 9 nanometers, or some other suitable range.

In some embodiments, the gate electrode 116 comprises polysilicon, a silicide, a metal (e.g., copper, tungsten, tungsten nitride, titanium nitride, or the like), or some other suitable material and has a width (e.g., along direction 101x) which is less than 50 nanometers, less than 30 nanometers, or some other suitable width.

In some embodiments, the first dielectric layer 102 and/or the second dielectric layer 104 comprise any of silicon oxide, silicon nitride, aluminum oxide, silicon oxycarbide, silicon carbonitride, or some other suitable material. In some embodiments, the first dielectric layer 102 and/or the second dielectric layer 104 have thicknesses (e.g., along direction 101z) which are greater than the thicknesses of the blocking layers 120, 122, 124. In some embodiments, the thicknesses of the first dielectric layer 102 and/or the second dielectric layer 104 range from about 10 nanometers to about 100 nanometers, about 20 nanometers to about 80 nanometers, or some other suitable range.

In some embodiments, the gate dielectric layer 114 comprises silicon oxide, aluminum oxide, hafnium oxide, a composite of hafnium oxide and zirconium oxide, a composite of hafnium oxide and aluminum oxide, a composite of hafnium oxide and lanthanum oxide, a composite of hafnium oxide and silicon oxide, a composite of hafnium oxide and strontium oxide, or some other suitable material. In some embodiments, the gate dielectric layer 114 has a thickness (e.g., along direction 101z) which is greater than the thicknesses of the blocking layers 120, 122, 124. In some embodiments, the thickness of the gate dielectric layer 114 ranges from about 10 nanometers to about 100 nanometers, about 20 nanometers to about 80 nanometers, or some other suitable range.

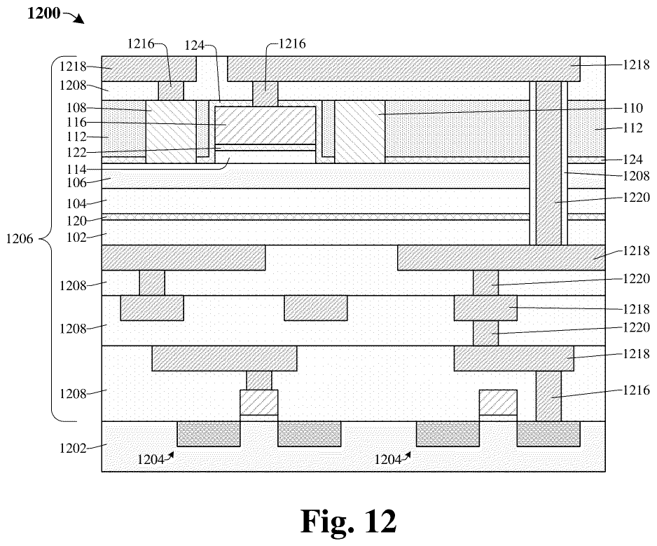

FIG. 12 illustrates a cross-sectional view 1200 of some embodiments of an integrated chip including the transistor device of FIG. 10 disposed within an interconnect structure 1206 over a semiconductor substrate 1202.

A plurality of front-end transistors devices 1204 are arranged along the semiconductor substrate 1202. An interconnect structure 1206 is over the semiconductor substrate 1202. The interconnect structure 1206 comprises a plurality of dielectric layers 1208 and a plurality of conductive interconnects (e.g. conductive contacts 1216, conductive lines 1218, conductive vias 1220, etc.) extending through the dielectric layers 1208. Some of the conductive interconnects of the interconnect structure 1206 are coupled to the front-end transistor devices 1204.

The interconnect structure 1206 further comprises the dielectric layers 102, 104, 112, 114, the active layer 106, the source/drain electrodes 108, 110, the gate electrode 116, and the blocking layers 120, 122, 124 that form the transistor device of FIG. 10. Contacts 1216 of the interconnect structure 1206 contact the source/drain electrodes 108, 110 and the gate electrode 116 of the transistor device. Some of the conductive vias 1220 and conductive lines 1218 of the interconnect structure 1206 couple the transistor device to some of the front-end transistor devices 1204.

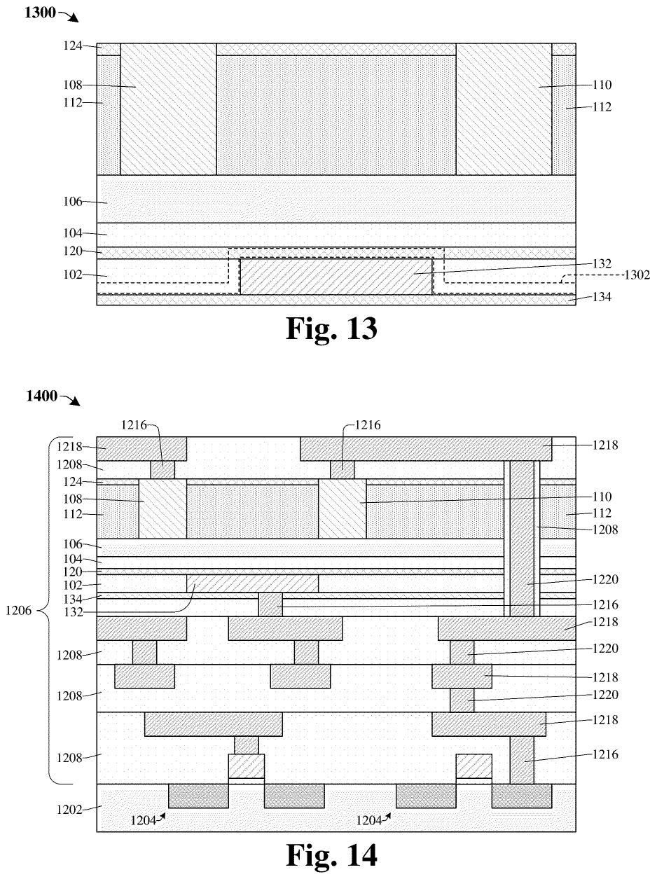

FIG. 13 illustrates a cross-sectional view 1300 of some embodiments of the transistor device of FIG. 1 in which the gate electrode 132 is under the active layer 106. FIG. 14 illustrates a cross-sectional view 1400 of some embodiments of an integrated chip including the transistor device of FIG. 13 disposed within an interconnect structure 1206 over a semiconductor substrate 1202.

The gate electrode 132 is spaced under the active layer 106 with the second dielectric layer 104 (e.g., gate dielectric layer) therebetween. Blocking layer 124 is over the active layer 106. Another blocking layer (e.g., blocking layer 120 and/or blocking layer 134) is under the active layer 106. In some embodiments, the transistor device includes blocking layer 120 directly between the gate electrode 132 and the second dielectric layer 104 (e.g., the gate dielectric layer). In some embodiments, the transistor device includes blocking layer 134 under the gate electrode 132 extending along a bottom surface of the gate electrode 132 and bottom surfaces of the first dielectric layer 102. In some embodiments, the transistor device includes both blocking layer 120 and blocking layer 134.

In some embodiments, blocking layer 120 extends laterally a top surface of the gate electrode 132 and along top surfaces of the first dielectric layer 102. In some other embodiments, blocking layer 120 extends laterally along the top surface of the gate electrode 132, vertically along sidewalls of the gate electrode 132, and laterally along bottom surfaces of the first dielectric layer 102 (e.g., as illustrated by dashed region 1302). In some such embodiments, blocking layer 120 extends along a top surface of blocking layer 134.

In the embodiments illustrated in FIGS. 13 and 14, blocking layer 120 comprises a different material(s) than blocking layer 124 and blocking layer 134. For example, in some embodiments, blocking layer 124 comprises a first oxide, blocking layer 134 comprises a second oxide, and blocking layer 120 comprises a third oxide different than the first oxide and the second oxide. In some embodiments, blocking layer 120 comprises indium oxide, indium tin oxide, indium zinc oxide, or some other suitable material. In some embodiments, blocking layer 124 and/or blocking layer 134 comprise any of silicon nitride, aluminum oxide, hafnium aluminum oxide, zirconium aluminum oxide, or some other suitable material.

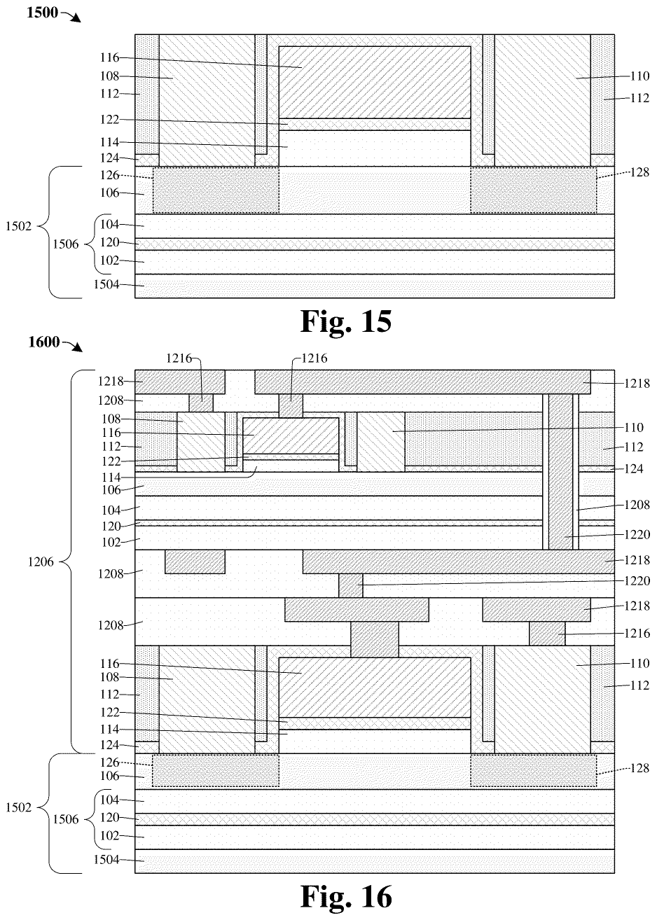

FIG. 15 illustrates a cross-sectional view 1500 of some embodiments of the transistor device of FIG. 1 in which the transistor device is disposed along a substrate 1502. FIG. 16 illustrates a cross-sectional view 1600 of some embodiments of an integrated chip including the transistor device of FIG. 15.

The substrate 1502 comprises a base semiconductor layer 1504, a base dielectric layer 1506 over the base semiconductor layer 1504, and the active layer 106 over the base dielectric layer 1506. The active layer 106 comprises a semiconductor (e.g., silicon or some other suitable material). In some embodiments, the base dielectric layer 1506 comprises the first dielectric layer 102, the second dielectric layer 104, and blocking layer 120. In some cases, the substrate 1502 may be referred to as a semiconductor-on-insulator (SOI) substrate. Blocking layer 122 and/or blocking layer 124 are over the active layer 106.

Source/drain regions are in the substrate 1502. For example, a first source/drain region 126 and a second source/drain region 128 are in the active layer 106 directly under the first source/drain electrode 108 and the second source/drain electrode 110, respectively. The source/drain regions 126, 128 have a first doping type (e.g., n type or p type) and the active layer 106 has a second doping type (e.g., p type or n type) different from the first doping type.

In some embodiments, the transistor device of FIG. 10 (and/or the transistor device of FIG. 13) is disposed within the interconnect structure 1206 and coupled to the transistor device of FIG. 15 by conductive interconnects of the interconnect structure 1206.

In the embodiments illustrated in FIGS. 15 and 16, blocking layer 122 comprises a different material(s) than blocking layer 120 and blocking layer 124. For example, in some embodiments, blocking layer 120 comprises a first oxide, blocking layer 124 comprises a second oxide, and blocking layer 122 comprises a third oxide different than the first oxide and the second oxide. In some embodiments, blocking layer 122 comprises indium oxide, indium tin oxide, indium zinc oxide, or some other suitable material. In some embodiments, blocking layer 120 and/or blocking layer 124 comprise any of silicon nitride, aluminum oxide, hafnium aluminum oxide, zirconium aluminum oxide, or some other suitable material.

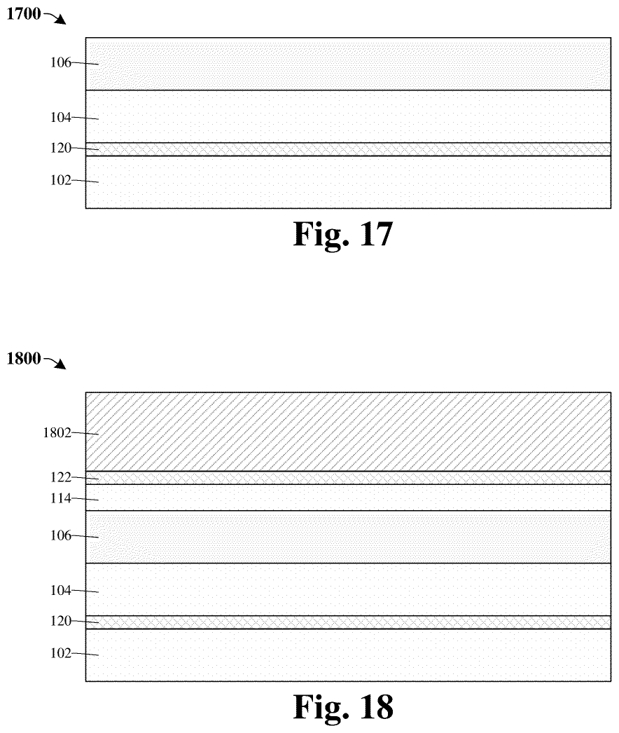

FIGS. 17-22 illustrate cross-sectional views 1700-2200 of some embodiments of a method for forming a transistor device comprising blocking layers 120, 122 surrounding an active layer 106. Although FIGS. 17-22 are described in relation to a method, it will be appreciated that the structures disclosed in FIGS. 17-22 are not limited to such a method, but instead may stand alone as structures independent of the method.

As shown in cross-sectional view 1700 of FIG. 17, blocking layer 120 is deposited over a first dielectric layer 102, a second dielectric layer 104 is deposited over blocking layer 120, and an active layer 106 is deposited over the second dielectric layer 104.

In some embodiments, the first dielectric layer 102 and/or the second dielectric layer 104 comprise silicon dioxide, silicon nitride, aluminum oxide, silicon oxycarbide, silicon carbonitride, or some other suitable material and are deposited by chemical vapor deposition (CVD) processes, physical vapor deposition (PVD) processes, atomic layer deposition (ALD) processes, or some other suitable processes.

In some embodiments, blocking layer 120 comprises silicon nitride, aluminum oxide, hafnium aluminum oxide, zirconium aluminum oxide, or some other suitable material and is deposited by a CVD process, a PVD process, an ALD process, or some other suitable process.

In some embodiments, the active layer 106 comprises silicon, amorphous silicon, polysilicon, copper oxide, tin oxide, indium oxide, indium zinc oxide (IZO), indium gallium oxide (IGO), indium gallium zinc oxide (IGZO), indium tungsten oxide (IWO), indium tungsten zinc oxide (IWZO), or some other suitable material and is deposited by a CVD process, a PVD process, an ALD process, or some other suitable process.

As shown in cross-sectional view 1800 of FIG. 18, a gate dielectric layer 114 is deposited over the active layer 106, blocking layer 122 is deposited over the gate dielectric layer 114, and a gate electrode layer 1802 is deposited over blocking layer 122.

In some embodiments, the gate dielectric layer 114 comprises silicon oxide, aluminum oxide, hafnium oxide, a composite of hafnium oxide and zirconium oxide, a composite of hafnium oxide and aluminum oxide, a composite of hafnium oxide and lanthanum oxide, a composite of hafnium oxide and silicon oxide, a composite of hafnium oxide and strontium oxide, or some other suitable material and is deposited by a CVD process, a PVD process, an ALD process, or some other suitable process.

In some embodiments, blocking layer 122 comprises indium oxide, indium tin oxide, indium zinc oxide, or some other suitable material, or some other suitable material and is deposited by a CVD process, a PVD process, an ALD process, or some other suitable process.

In some embodiments, the gate electrode layer 1802 comprises polysilicon, a silicide, a metal (e.g., copper, tungsten, tungsten nitride, titanium nitride, or the like), or some other suitable material and is deposited by a CVD process, a PVD process, an ALD process, or some other suitable process.

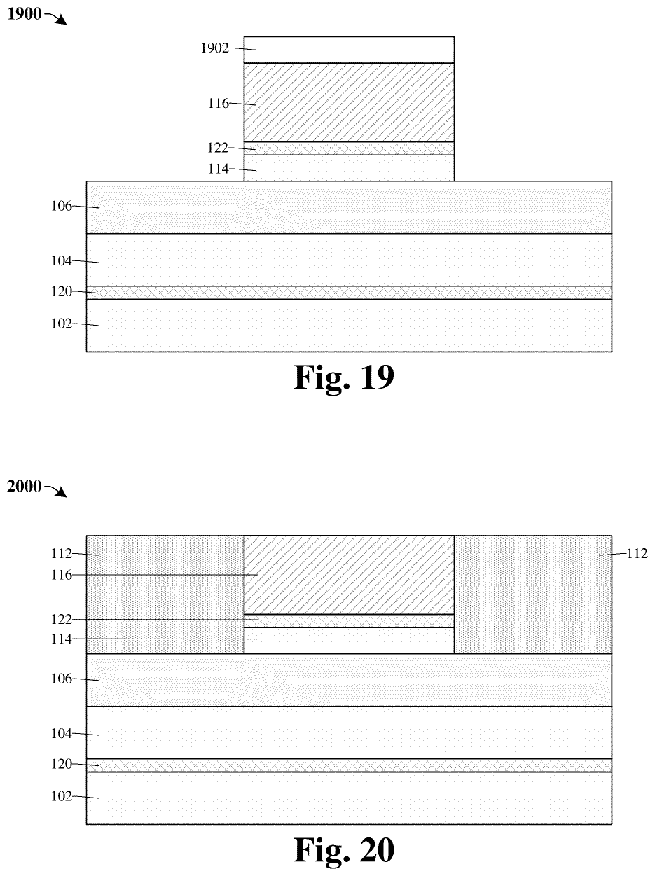

As shown in cross-sectional view 1900 of FIG. 19, the gate electrode layer 1802, blocking layer 122, and the gate dielectric layer 114 are etched to delimit the gate electrode 116 from the gate electrode layer 1802 and to further delimit blocking layer 122 and the gate dielectric layer 114. In some embodiments, a masking layer 1902 is formed over the gate electrode layer 1802 and the etching is performed according to the masking layer 1902. In some embodiments, the masking layer 1902 comprises photoresist or some other suitable material. In some embodiments, the etching comprises a dry etching process (e.g., a plasma etching process, a reactive ion etching process, an ion beam etching process, or the like) or some other suitable process.

As shown in cross-sectional view 2000 of FIG. 20, a third dielectric layer 112 is deposited over the active layer 106 and beside the gate electrode 116 on opposite sides of the gate electrode 116. In some embodiments, the third dielectric layer 112 comprises silicon dioxide, silicon nitride, silicon oxycarbide, or some other suitable material and is deposited by a CVD process, a PVD process, an ALD process, or some other suitable process. In some embodiments, the third dielectric layer 112 is deposited over the gate electrode 116 and a polishing/planarization process (e.g., a blanket etch back process, a chemical mechanical polishing/planarizing (CMP) process, or the like) is performed on the third dielectric layer 112 to remove the third dielectric layer 112 from over the gate electrode 116 after deposition.

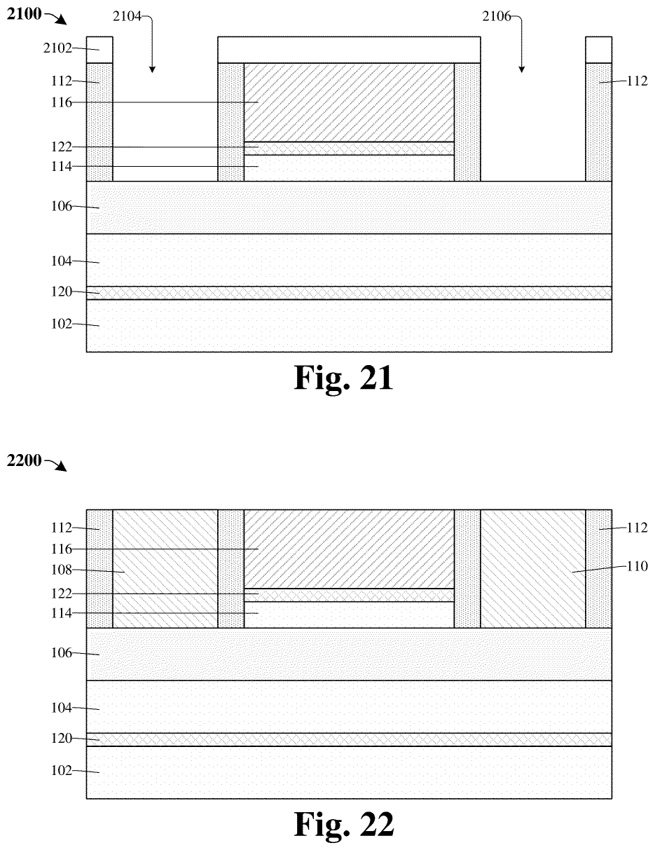

As shown in cross-sectional view 2100 of FIG. 21, the third dielectric layer 112 is etched to form a first opening 2104 and a second opening 2106 in the third dielectric layer 112. The etching uncovers portions of the active layer 106 at the openings 2104, 2106. In some embodiments, a masking layer 2102 is formed over third dielectric layer 112 and the gate electrode 116 and the etching is performed according to the masking layer 2102. In some embodiments, the masking layer 2102 comprises photoresist or some other suitable material. In some embodiments, the etching comprises a dry etching process or some other suitable process.

As shown in cross-sectional view 2200 of FIG. 22, a conductive layer (not labeled) is deposited in the first opening 2104 and the second opening 2106 to form a first source/drain electrode 108 and a second source/drain electrode 110 in the first opening 2104 and the second opening 2106, respectively. In some embodiments, the conductive layer (not labeled) comprises a metal (e.g., tungsten, copper, aluminum, or the like) or some other suitable material and is deposited by a CVD process, a PVD process, an ALD process, or some other suitable process. In some embodiments, the conductive layer (not labeled) is deposited over the third dielectric layer 112 and the gate electrode 116, and a polishing/planarization process is performed on the conductive layer to remove the conductive layer from over the third dielectric layer 112 and the gate electrode 116 after deposition.

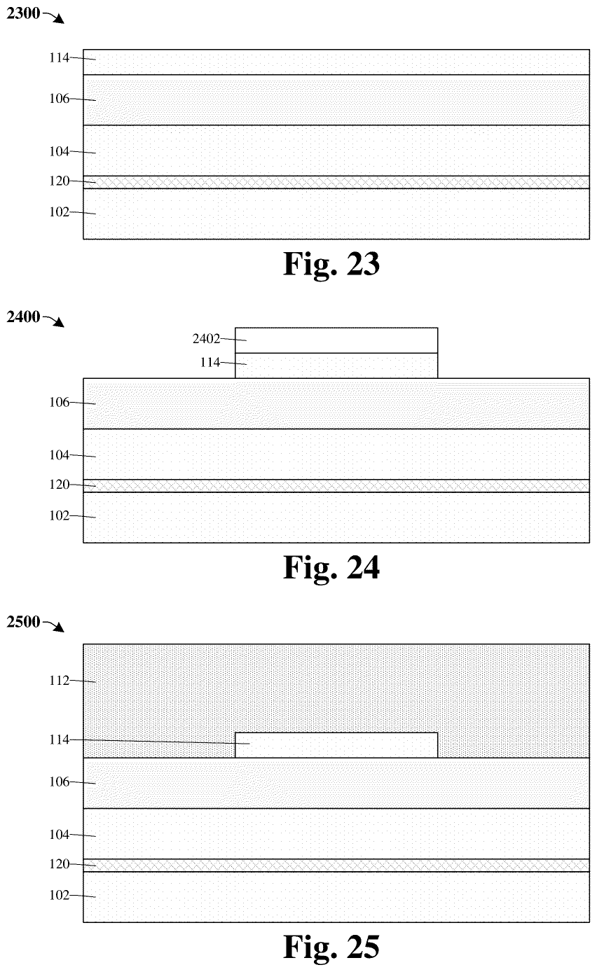

FIGS. 23-29 illustrate cross-sectional views 2300-2900 of some other embodiments of a method for forming a transistor device comprising blocking layers 120, 122 surrounding an active layer 106. Although FIGS. 23-29 are described in relation to a method, it will be appreciated that the structures disclosed in FIGS. 23-29 are not limited to such a method, but instead may stand alone as structures independent of the method.

As shown in cross-sectional view 2300 of FIG. 23, blocking layer 120 is deposited over a first dielectric layer 102, a second dielectric layer 104 is deposited over blocking layer 120, an active layer 106 is deposited over the second dielectric layer 104, and a gate dielectric layer 114 is deposited over the active layer 106. In some embodiments, blocking layer 120 comprises silicon nitride, aluminum oxide, hafnium aluminum oxide, zirconium aluminum oxide, or some other suitable material and is deposited by a CVD process, a PVD process, an ALD process, or some other suitable process.

As shown in cross-sectional view 2400 of FIG. 24, the gate dielectric layer 114 is etched to further delimit the gate dielectric layer 114 over the active layer 106. The etching uncovers portions of the active layer 106 on opposite sides of the gate dielectric layer 114. In some embodiments, a masking layer 2402 is formed over gate dielectric layer 114 and the etching is performed according to the masking layer 2402. In some embodiments, the masking layer 2402 comprises photoresist or some other suitable material. In some embodiments, the etching comprises a dry etching process or some other suitable process.

As shown in cross-sectional view 2500 of FIG. 25, a third dielectric layer 112 is deposited over the active layer 106 and over the gate dielectric layer 114.

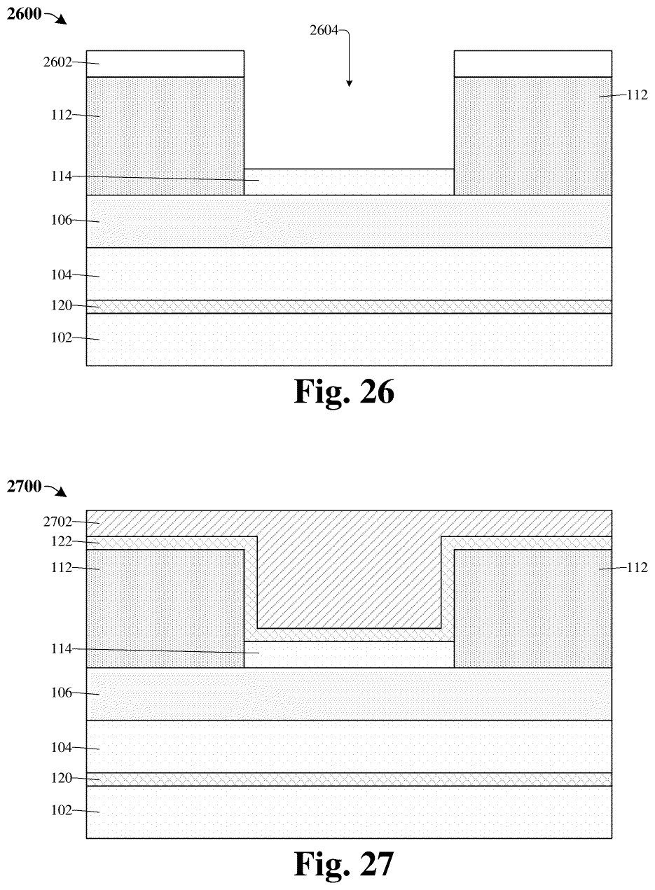

As shown in cross-sectional view 2600 of FIG. 26, the third dielectric layer 112 is etched to form an opening 2604 in the third dielectric layer 112. The etching uncovers the gate dielectric layer 114 at the opening 2604. In some embodiments, a masking layer 2602 is formed over third dielectric layer 112 and the etching is performed according to the masking layer 2602. In some embodiments, the masking layer 2602 comprises photoresist or some other suitable material. In some embodiments, the etching comprises a dry etching process or some other suitable process.

As shown in cross-sectional view 2700 of FIG. 27, blocking layer 122 is deposited over the third dielectric layer 112 and in opening 2604 on the gate dielectric layer 114. A gate electrode layer 2702 is deposited over blocking layer 122 and in opening 2604.

In some embodiments, blocking layer 122 comprises indium oxide, indium tin oxide, indium zinc oxide, or some other suitable material, or some other suitable material and is deposited by a CVD process, a PVD process, an ALD process, or some other suitable process. In some embodiments, the gate electrode layer 2702 comprises polysilicon, a silicide, a metal (e.g., copper, tungsten, tungsten nitride, titanium nitride, or the like), or some other suitable material and is deposited by a CVD process, a PVD process, an ALD process, or some other suitable process.

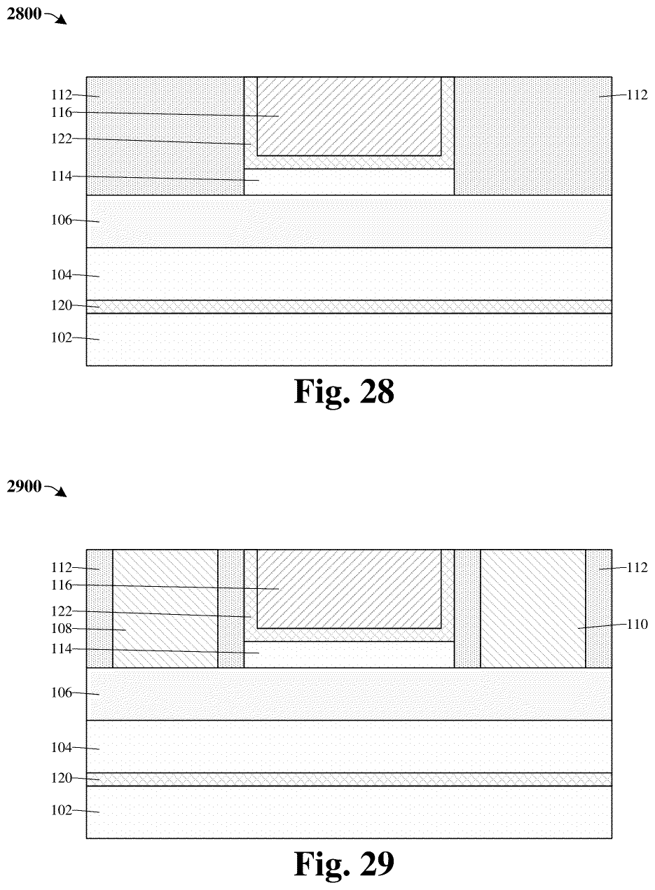

As shown in cross-sectional view 2800 of FIG. 28, a polishing/planarization process is performed on the gate electrode layer 2702 and blocking layer 122 to remove the gate electrode layer 2702 and blocking layer 122 from over the third dielectric layer 112 and to form the gate electrode 116 from the gate electrode layer 2702. In some embodiments, the polishing/planarization process comprises a blanket etch back process, a chemical mechanical polishing/planarizing (CMP) process, or some other suitable process.

As shown in cross-sectional view 2900 of FIG. 29, a first source/drain electrode 108 and a second source/drain electrode 110 are formed within the third dielectric layer 112 and on the active layer 106. In some embodiments, forming the source/drain electrodes 108, 110 comprises etching the third dielectric layer 112 to form openings in the third dielectric layer 112, depositing a conductive layer in the openings, and performing a polishing/planarization process on the conductive layer after deposition (e.g., as described with regard to FIGS. 21, 22).

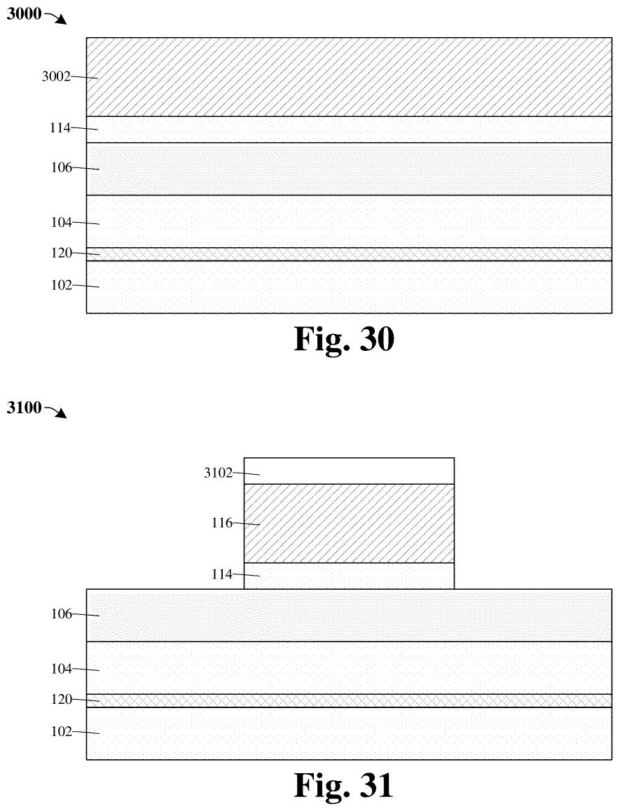

FIGS. 30-33 illustrate cross-sectional views 3000-3300 of some embodiments of a method for forming a transistor device comprising blocking layers 120, 124 surrounding an active layer 106. Although FIGS. 30-33 are described in relation to a method, it will be appreciated that the structures disclosed in FIGS. 30-33 are not limited to such a method, but instead may stand alone as structures independent of the method.

As shown in cross-sectional view 3000 of FIG. 30, blocking layer 120 is deposited over a first dielectric layer 102, a second dielectric layer 104 is deposited over blocking layer 120, an active layer 106 is deposited over the second dielectric layer 104, a gate dielectric layer 114 is deposited over the active layer 106, and a gate electrode layer 3002 is deposited over the gate dielectric layer 114.

In some embodiments, blocking layer 120 comprises silicon nitride, aluminum oxide, hafnium aluminum oxide, zirconium aluminum oxide, or some other suitable material and is deposited by a CVD process, a PVD process, an ALD process, or some other suitable process. In some embodiments, the gate electrode layer 3002 comprises polysilicon, a silicide, a metal (e.g., copper, tungsten, tungsten nitride, titanium nitride, or the like), or some other suitable material and is deposited by a CVD process, a PVD process, an ALD process, or some other suitable process.

As shown in cross-sectional view 3100 of FIG. 31, the gate electrode layer 3002 and the gate dielectric layer 114 are etched to delimit the gate electrode 116 from the gate electrode layer 3002 and to further delimit the gate dielectric layer 114. In some embodiments, a masking layer 3102 is formed over the gate electrode layer 3002 and the etching is performed according to the masking layer 3102. In some embodiments, the masking layer 3102 comprises photoresist or some other suitable material. In some embodiments, the etching comprises a dry etching process or some other suitable process.

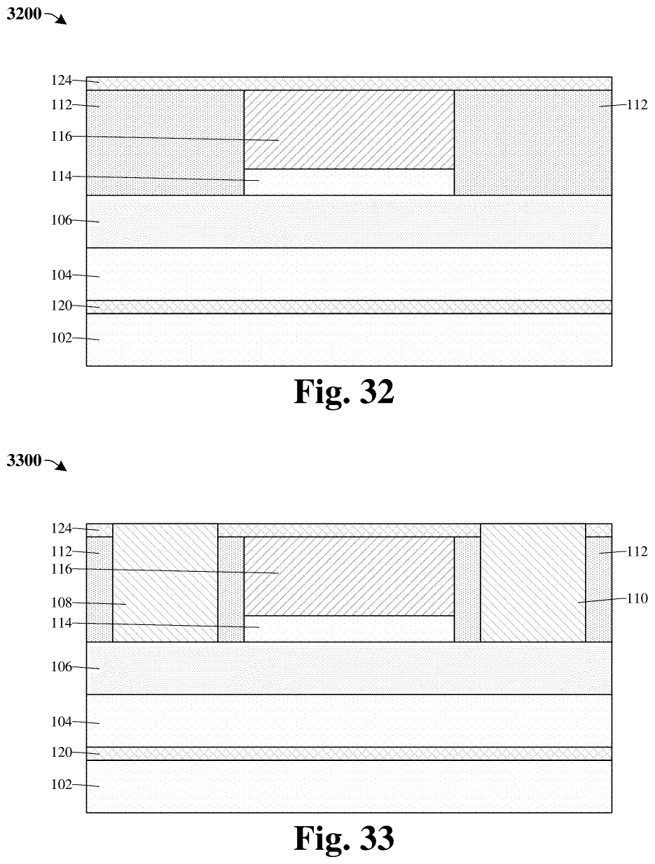

As shown in cross-sectional view 3200 of FIG. 32, a third dielectric layer 112 is deposited over the active layer 106 and beside the gate electrode 116 on opposite sides of the gate electrode 116. In some embodiments, the third dielectric layer 112 is deposited over the gate electrode 116 and a polishing/planarization process is performed on the third dielectric layer 112 to remove the third dielectric layer 112 from over the gate electrode 116 after deposition.

Further, as shown in cross-sectional view 3200 of FIG. 32, blocking layer 124 is deposited over the third dielectric layer 112 and the gate electrode 116. In some embodiments, blocking layer 124 comprises silicon nitride, aluminum oxide, hafnium aluminum oxide, zirconium aluminum oxide, or some other suitable material and is deposited by a CVD process, a PVD process, an ALD process, or some other suitable process.

As shown in cross-sectional view 3300 of FIG. 33, a first source/drain electrode 108 and a second source/drain electrode 110 are formed within blocking layer 124 and the third dielectric layer 112 and on the active layer 106. In some embodiments, forming the source/drain electrodes 108, 110 comprises etching blocking layer 124 and the third dielectric layer 112 to form openings therein, depositing a conductive layer in the openings, and performing a polishing/planarization process on the conductive layer after deposition (e.g., as described with regard to FIGS. 21, 22).

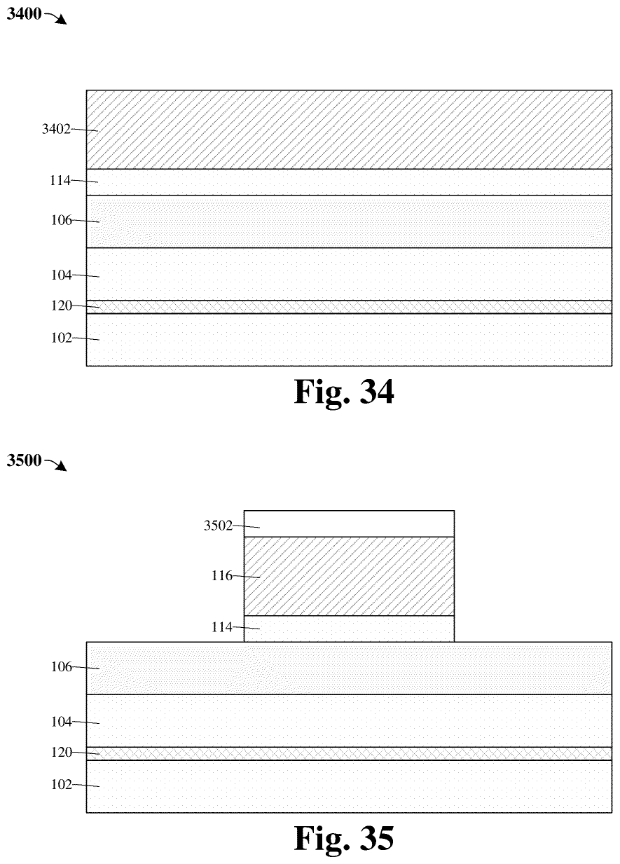

FIGS. 34-37 illustrate cross-sectional views 3400-3700 of some other embodiments of a method for forming a transistor device comprising blocking layers 120, 124 surrounding an active layer 106. Although FIGS. 34-37 are described in relation to a method, it will be appreciated that the structures disclosed in FIGS. 34-37 are not limited to such a method, but instead may stand alone as structures independent of the method.

As shown in cross-sectional view 3400 of FIG. 34, blocking layer 120 is deposited over a first dielectric layer 102, a second dielectric layer 104 is deposited over blocking layer 120, an active layer 106 is deposited over the second dielectric layer 104, a gate dielectric layer 114 is deposited over the active layer 106, and a gate electrode layer 3402 is deposited over the gate dielectric layer 114.

In some embodiments, blocking layer 120 comprises silicon nitride, aluminum oxide, hafnium aluminum oxide, zirconium aluminum oxide, or some other suitable material and is deposited by a CVD process, a PVD process, an ALD process, or some other suitable process. In some embodiments, the gate electrode layer 3402 comprises polysilicon, a silicide, a metal (e.g., copper, tungsten, tungsten nitride, titanium nitride, or the like), or some other suitable material and is deposited by a CVD process, a PVD process, an ALD process, or some other suitable process.

As shown in cross-sectional view 3500 of FIG. 35, the gate electrode layer 3402 and the gate dielectric layer 114 are etched to delimit the gate electrode 116 from the gate electrode layer 3402 and to further delimit the gate dielectric layer 114. In some embodiments, a masking layer 3502 is formed over the gate electrode layer 3402 and the etching is performed according to the masking layer 3502. In some embodiments, the masking layer 3502 comprises photoresist or some other suitable material. In some embodiments, the etching comprises a dry etching process or some other suitable process.

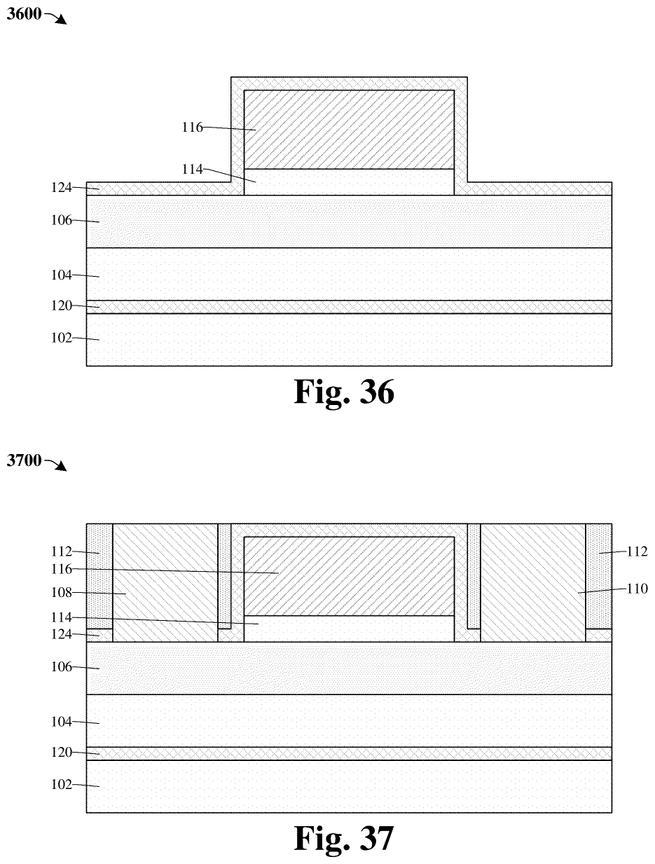

As shown in cross-sectional view 3600 of FIG. 36, blocking layer 124 is deposited over the gate electrode 116, along sidewalls of the gate electrode 116, along sidewalls of the gate dielectric layer 114, and over the active layer 106. In some embodiments, blocking layer 124 comprises silicon nitride, aluminum oxide, hafnium aluminum oxide, zirconium aluminum oxide, or some other suitable material and is deposited by a CVD process, a PVD process, an ALD process, or some other suitable process.

As shown in cross-sectional view 3700 of FIG. 37, a third dielectric layer 112 is deposited over blocking layer 124 and beside the gate electrode 116 on opposite sides of the gate electrode 116. Further, a first source/drain electrode 108 and a second source/drain electrode 110 are formed within the third dielectric layer 112 and blocking layer 124 and on the active layer 106. In some embodiments, forming the source/drain electrodes 108, 110 comprises etching the third dielectric layer 112 and blocking layer 124 to form openings therein, depositing a conductive layer in the openings, and performing a polishing/planarization process on the conductive layer after deposition (e.g., as described with regard to FIGS. 21, 22).

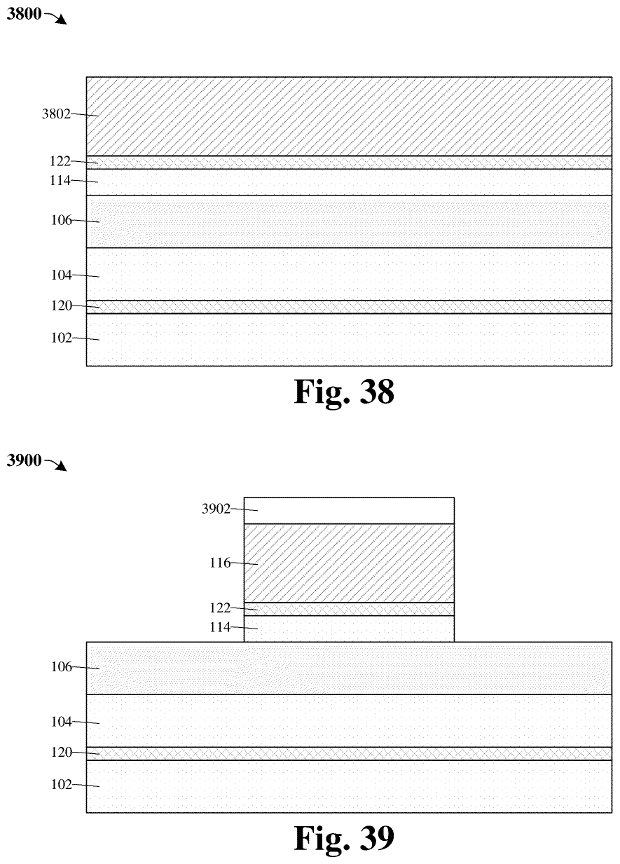

FIGS. 38-41 illustrate cross-sectional views 3800-4100 of some embodiments of a method for forming a transistor device comprising blocking layers 120, 122, 124 surrounding an active layer 106. Although FIGS. 38-41 are described in relation to a method, it will be appreciated that the structures disclosed in FIGS. 38-41 are not limited to such a method, but instead may stand alone as structures independent of the method.

As shown in cross-sectional view 3800 of FIG. 38, blocking layer 120 is deposited over a first dielectric layer 102, a second dielectric layer 104 is deposited over blocking layer 120, an active layer 106 is deposited over the second dielectric layer 104, a gate dielectric layer 114 is deposited over the active layer 106, blocking layer 122 is deposited over the gate dielectric layer 114, and a gate electrode layer 3802 is deposited over the gate dielectric layer 114.

In some embodiments, blocking layer 120 comprises silicon nitride, aluminum oxide, hafnium aluminum oxide, zirconium aluminum oxide, or some other suitable material and is deposited by a CVD process, a PVD process, an ALD process, or some other suitable process. In some embodiments, blocking layer 122 comprises indium oxide, indium tin oxide, indium zinc oxide, or some other suitable material, or some other suitable material and is deposited by a CVD process, a PVD process, an ALD process, or some other suitable process. In some embodiments, the gate electrode layer 3802 comprises polysilicon, a silicide, a metal (e.g., copper, tungsten, tungsten nitride, titanium nitride, or the like), or some other suitable material and is deposited by a CVD process, a PVD process, an ALD process, or some other suitable process.

As shown in cross-sectional view 3900 of FIG. 39, the gate electrode layer 3802, blocking layer 122, and the gate dielectric layer 114 are etched to delimit the gate electrode 116 from the gate electrode layer 3802 and to further delimit blocking layer 122 and the gate dielectric layer 114. In some embodiments, a masking layer 3902 is formed over the gate electrode layer 3802 and the etching is performed according to the masking layer 3902. In some embodiments, the masking layer 3902 comprises photoresist or some other suitable material. In some embodiments, the etching comprises a dry etching process or some other suitable process.

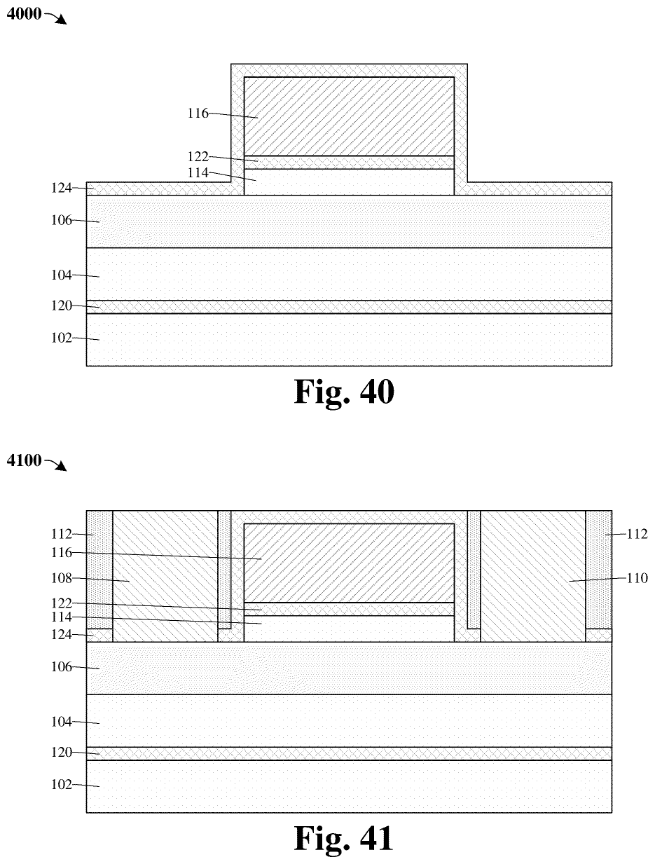

As shown in cross-sectional view 4000 of FIG. 40, blocking layer 124 is deposited over the gate electrode 116, along sidewalls of the gate electrode 116, along sidewalls of blocking layer 122, along sidewalls of the gate dielectric layer 114, and over the active layer 106. In some embodiments, blocking layer 124 comprises silicon nitride, aluminum oxide, hafnium aluminum oxide, zirconium aluminum oxide, or some other suitable material and is deposited by a CVD process, a PVD process, an ALD process, or some other suitable process.

As shown in cross-sectional view 4100 of FIG. 41, a third dielectric layer 112 is deposited over blocking layer 124 and beside the gate electrode 116 on opposite sides of the gate electrode 116. Further, a first source/drain electrode 108 and a second source/drain electrode 110 are formed within the third dielectric layer 112 and blocking layer 124 and on the active layer 106. In some embodiments, forming the source/drain electrodes 108, 110 comprises etching the third dielectric layer 112 and blocking layer 124 to form openings therein, depositing a conductive layer in the openings, and performing a polishing/planarization process on the conductive layer after deposition (e.g., as described with regard to FIGS. 21, 22).

In some embodiments of the methods illustrated in FIGS. 17-41, a plurality of front-end transistor devices (e.g., front-end transistor devices 1204 of FIG. 12) are formed along a semiconductor substrate (e.g., semiconductor substrate 1202 of FIG. 12), and the transistor device is formed over the front-end transistors within an interconnect structure (e.g., interconnect structure 1206 of FIG. 12). Further, in some embodiments of the methods illustrated in FIGS. 17-41, the first dielectric layer 102 is deposited on a dielectric layer and/or one or more conductive interconnects of the interconnect structure (e.g., interconnect structure 1206 of FIG. 12).

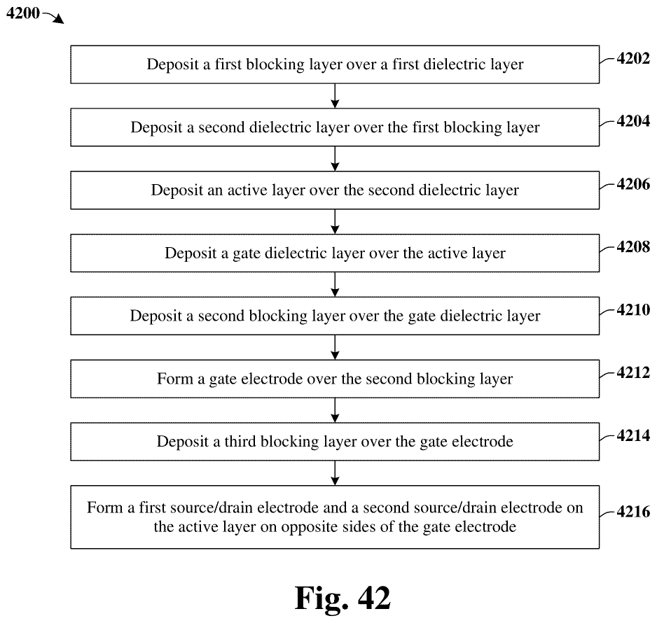

FIG. 42 illustrates a flow diagram of some embodiments of a method 4200 for forming a transistor device comprising blocking layers surrounding an active layer. While method 4200 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At block 4202, deposit a first blocking layer over a first dielectric layer. FIGS. 17, 23, 30, 34, 38 illustrate respective cross-sectional views 1700, 2300, 3000, 3400, 3800 of some embodiments corresponding to block 4202.

At block 4204, deposit a second dielectric layer over the first blocking layer. FIGS. 17, 23, 30, 34, 38 illustrate respective cross-sectional views 1700, 2300, 3000, 3400, 3800 of some embodiments corresponding to block 4204.

At block 4206, deposit an active layer over the second dielectric layer. FIGS. 17, 23, 30, 34, 38 illustrate respective cross-sectional views 1700, 2300, 3000, 3400, 3800 of some embodiments corresponding to block 4206.

At block 4208, deposit a gate dielectric layer over the active layer. FIGS. 18, 23, 30, 34, 38 illustrate respective cross-sectional views 1800, 2300, 3000, 3400, 3800 of some embodiments corresponding to block 4208.

At block 4210, deposit a second blocking layer over the gate dielectric layer. FIGS. 18, 27, 38 illustrate respective cross-sectional views 1800, 2700, 3800 of some embodiments corresponding to block 4210.

At block 4212, form a gate electrode over the second blocking layer. FIGS. 19, 28, 31, 35, 39 illustrate respective cross-sectional views 1900, 2800, 3100, 3500, 3900 of some embodiments corresponding to block 4212.

At block 4214, deposit a third blocking layer over the gate electrode. FIGS. 32, 36, 40 illustrate respective cross-sectional views 3200, 3600, 4000 of some embodiments corresponding to block 4214.

At block 4216, form a first source/drain electrode and a second source/drain electrode on the active layer on opposite sides of the gate electrode. FIGS. 22, 29, 33, 37, 41 illustrate respective cross-sectional views 2200, 2900, 3300, 3700, 4100 of some embodiments corresponding to block 4216.

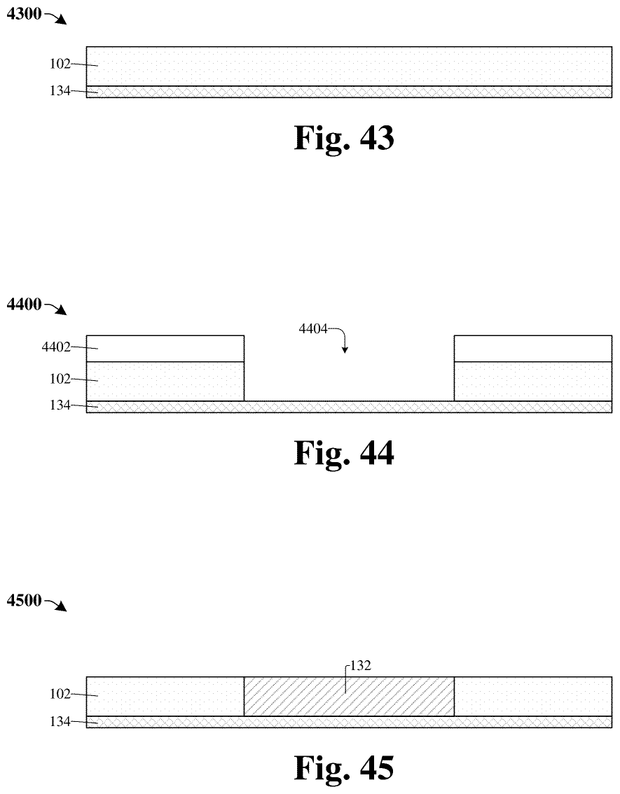

FIGS. 43-47 illustrate cross-sectional views 4300-4700 of some other embodiments of a method for forming a transistor device comprising blocking layers 120, 124, 134 surrounding an active layer 106. Although FIGS. 43-47 are described in relation to a method, it will be appreciated that the structures disclosed in FIGS. 43-47 are not limited to such a method, but instead may stand alone as structures independent of the method.

As shown in cross-sectional view 4300 of FIG. 43, a first dielectric layer 102 is deposited over blocking layer 134. In some embodiments, blocking layer 134 comprises silicon nitride, aluminum oxide, hafnium aluminum oxide, zirconium aluminum oxide, or some other suitable material and is deposited by a CVD process, a PVD process, an ALD process, or some other suitable process. In some embodiments, blocking layer 134 deposited on a dielectric layer of an interconnect structure (e.g., interconnect structure 1206 of FIG. 14).

As shown in cross-sectional view 4400 of FIG. 44, the first dielectric layer 102 is etched to form an opening 4404 in the first dielectric layer 102. The etching uncovers a portion of blocking layer 134 at the opening 4404. In some embodiments, a masking layer 4402 is formed over first dielectric layer 102 and the etching is performed according to the masking layer 4402. In some embodiments, the masking layer 4402 comprises photoresist or some other suitable material. In some embodiments, the etching comprises a dry etching process or some other suitable process.

As shown in cross-sectional view 4500 of FIG. 45, a gate electrode 132 is formed on blocking layer 134 in the opening 4404 (between sidewalls of the first dielectric layer 102). In some embodiments, the gate electrode 132 is formed by depositing a gate electrode layer (not labeled) comprising polysilicon, a silicide, a metal, or some other suitable material over the first dielectric layer 102 and in opening 4404, and by performing a polishing/planarization process on the gate electrode layer to remove the gate electrode layer from over the first dielectric layer 102 and to form the gate electrode 132 from the gate electrode layer.

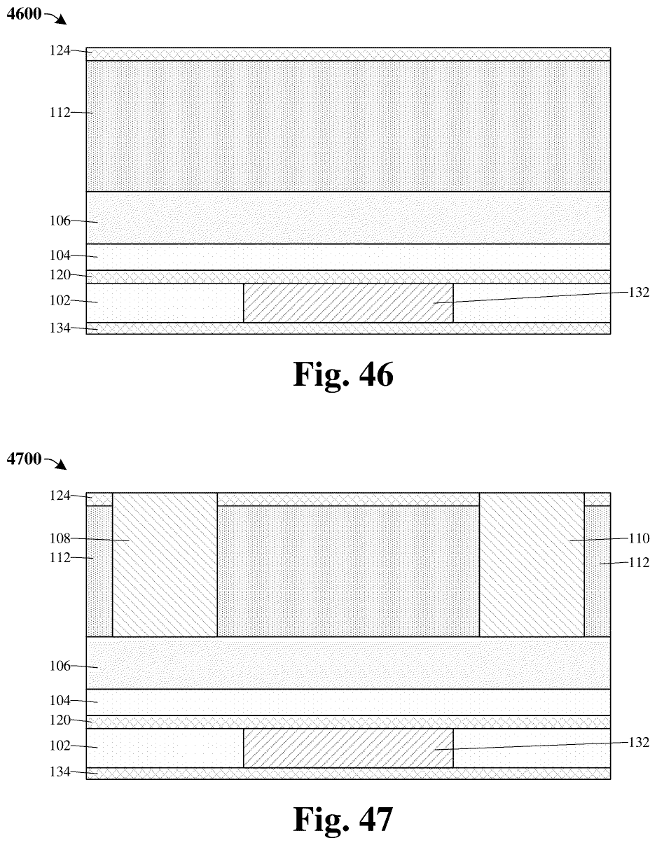

As shown in cross-sectional view 4600 of FIG. 46, blocking layer 120 is deposited over the first dielectric layer 102 and the gate electrode 132, a second dielectric layer 104 (e.g., the gate dielectric layer) is deposited over blocking layer 120, an active layer 106 is deposited over the second dielectric layer 104, a third dielectric layer 112 is deposited over the active layer 106, and blocking layer 124 is deposited over the third dielectric layer 112.

In some embodiments, blocking layer 120 comprises indium oxide, indium tin oxide, indium zinc oxide, or some other suitable material, or some other suitable material and is deposited by a CVD process, a PVD process, an ALD process, or some other suitable process. In some embodiments, blocking layer 124 comprises silicon nitride, aluminum oxide, hafnium aluminum oxide, zirconium aluminum oxide, or some other suitable material and is deposited by a CVD process, a PVD process, an ALD process, or some other suitable process.

As shown in cross-sectional view 4700 of FIG. 47, a first source/drain electrode 108 and a second source/drain electrode 110 are formed within the third dielectric layer 112 and blocking layer 124 and on the active layer 106. In some embodiments, forming the source/drain electrodes 108, 110 comprises etching blocking layer 124 and the third dielectric layer 112 to form openings therein, depositing a conductive layer in the openings, and performing a polishing/planarization process on the conductive layer after deposition (e.g., as described with regard to FIGS. 21, 22).

In some embodiments of the method illustrated in FIGS. 43-47, a plurality of front-end transistor devices (e.g., front-end transistor devices 1204 of FIG. 14) are formed along a semiconductor substrate (e.g., semiconductor substrate 1202 of FIG. 14), and the transistor device is formed over the front-end transistors within an interconnect structure (e.g., interconnect structure 1206 of FIG. 14).

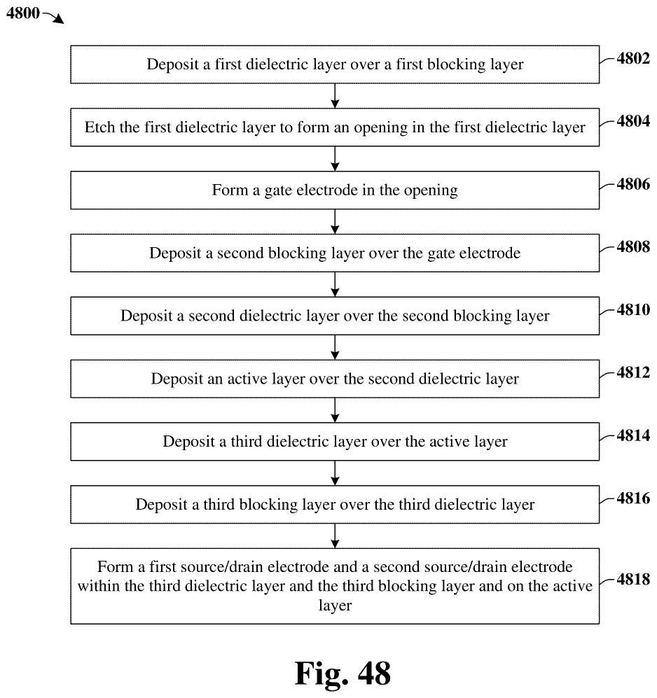

FIG. 48 illustrates a flow diagram of some embodiments of a method 4800 for forming a transistor device comprising blocking layers surrounding an active layer. While method 4800 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At block 4802, deposit a first dielectric layer over a first blocking layer. FIG. 43 illustrates cross-sectional view 4300 of some embodiments corresponding to block 4802.

At block 4804, etch the first dielectric layer to form an opening in the first dielectric layer. FIG. 44 illustrates cross-sectional view 4400 of some embodiments corresponding to block 4804.

At block 4806, form a gate electrode in the opening. FIG. 45 illustrates cross-sectional view 4500 of some embodiments corresponding to block 4806.

At block 4808, deposit a second blocking layer over the gate electrode. FIG. 46 illustrates cross-sectional view 4600 of some embodiments corresponding to block 4808.

At block 4810, deposit a second dielectric layer (e.g., a gate dielectric layer) over the second blocking layer. FIG. 46 illustrates cross-sectional view 4600 of some embodiments corresponding to block 4810.

At block 4812, deposit an active layer over the second dielectric layer. FIG. 46 illustrates cross-sectional view 4600 of some embodiments corresponding to block 4812.

At block 4814, deposit a third dielectric layer over the active layer. FIG. 46 illustrates cross-sectional view 4600 of some embodiments corresponding to block 4814.

At block 4816, deposit a third blocking layer over the third dielectric layer. FIG. 46 illustrates cross-sectional view 4600 of some embodiments corresponding to block 4816.

At block 4818, form a first source/drain electrode and a second source/drain electrode within the third dielectric layer and the third blocking layer and on the active layer. FIG. 47 illustrates cross-sectional view 4700 of some embodiments corresponding to block 4818.

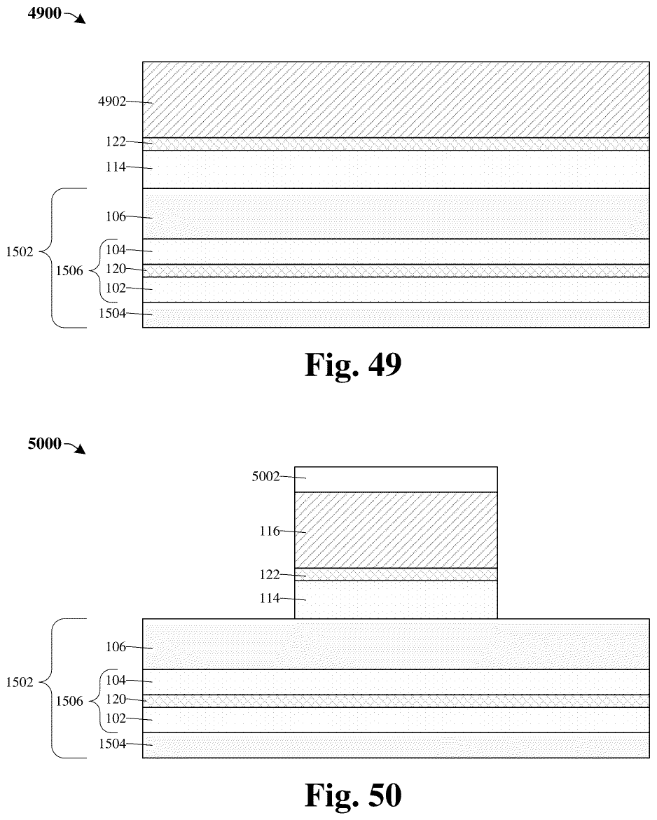

FIGS. 49-53 illustrate cross-sectional views 4900-5300 of some other embodiments of a method for forming a transistor device comprising blocking layers 120, 122, 124 surrounding an active layer 106. Although FIGS. 49-53 are described in relation to a method, it will be appreciated that the structures disclosed in FIGS. 49-53 are not limited to such a method, but instead may stand alone as structures independent of the method.

As shown in cross-sectional view 4900 of FIG. 49, a gate dielectric layer 114 is deposited over a substrate 1502, blocking layer 122 is deposited over the gate dielectric layer 114, and a gate electrode layer 4902 is deposited over blocking layer 122. In some embodiments, the substrate 1502 is formed by forming a base dielectric layer 1506 between a base semiconductor layer 1504 and an active layer 106. In some embodiments, the base dielectric layer 1506 comprises blocking layer 120, a first dielectric layer 102, and a second dielectric layer 104.

In some embodiments, the base semiconductor layer 1504 comprises silicon or some other suitable material. In some embodiments, blocking layer 120 comprises silicon nitride, aluminum oxide, hafnium aluminum oxide, zirconium aluminum oxide, or some other suitable material. In some embodiments, blocking layer 122 comprises indium oxide, indium tin oxide, indium zinc oxide, or some other suitable material, or some other suitable material and is deposited by a CVD process, a PVD process, an ALD process, or some other suitable process. In some embodiments, the gate electrode layer 4902 comprises polysilicon, a silicide, a metal (e.g., copper, tungsten, tungsten nitride, titanium nitride, or the like), or some other suitable material and is deposited by a CVD process, a PVD process, an ALD process, or some other suitable process.

As shown in cross-sectional view 5000 of FIG. 50, the gate electrode layer 4902, blocking layer 122, and the gate dielectric layer 114 are etched to delimit the gate electrode 116 from the gate electrode layer 4902 and to further delimit blocking layer 122 and the gate dielectric layer 114. In some embodiments, a masking layer 5002 is formed over the gate electrode layer 4902 and the etching is performed according to the masking layer 5002. In some embodiments, the masking layer 5002 comprises photoresist or some other suitable material. In some embodiments, the etching comprises a dry etching process or some other suitable process.

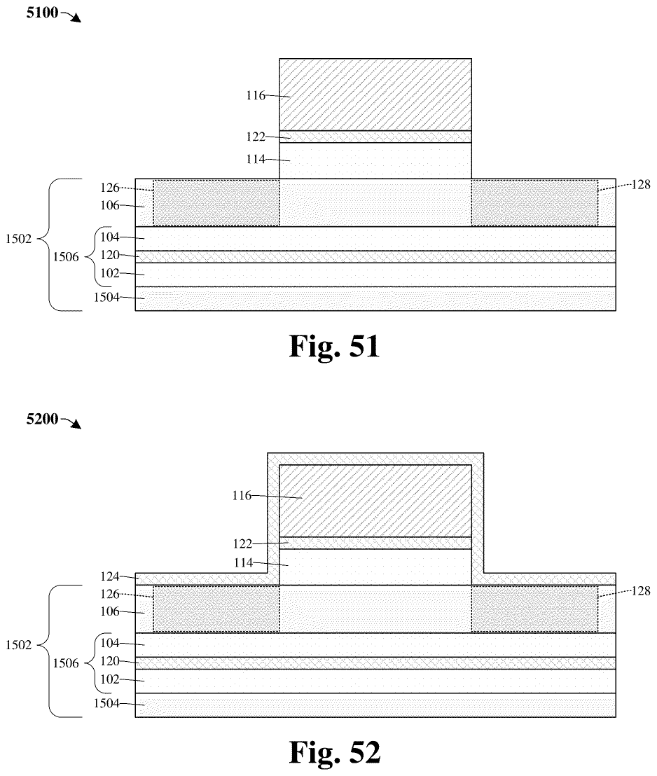

As shown in cross-sectional view 5100 of FIG. 51, portions of the active layer 106 are doped to form a first source/drain region 126 and a second source/drain region 128 in the active layer 106. In some embodiments, doping the active layer 106 comprises performing an ion implantation process or some other suitable doping process. The source/drain regions 126, 128 are formed to have a doping type different than that of the active layer 106.

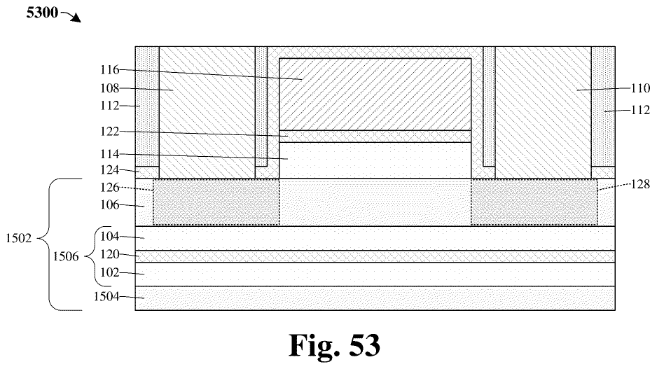

As shown in cross-sectional view 5200 of FIG. 52, blocking layer 124 is deposited over the gate electrode 116, along sidewalls of the gate electrode 116, along sidewalls of blocking layer 122, along sidewalls of the gate dielectric layer 114, and over the active layer 106. In some embodiments, blocking layer 124 comprises silicon nitride, aluminum oxide, hafnium aluminum oxide, zirconium aluminum oxide, or some other suitable material and is deposited by a CVD process, a PVD process, an ALD process, or some other suitable process.

As shown in cross-sectional view 5300 of FIG. 53, a third dielectric layer 112 is deposited over blocking layer 124 and beside the gate electrode 116 on opposite sides of the gate electrode 116. Further, a first source/drain electrode 108 and a second source/drain electrode 110 are formed within the third dielectric layer 112 and blocking layer 124 and on the active layer 106. In some embodiments, forming the source/drain electrodes 108, 110 comprises etching the third dielectric layer 112 and blocking layer 124 to form openings therein, depositing a conductive layer in the openings, and performing a polishing/planarization process on the conductive layer after deposition (e.g., as described with regard to FIGS. 21, 22).

In some embodiments of the method illustrated in FIGS. 49-53, an interconnect structure (e.g., interconnect structure 1206 of FIG. 16) is formed over the transistor device, and one or more additional transistor devices are formed within the interconnect structure (e.g., as shown in FIG. 16).

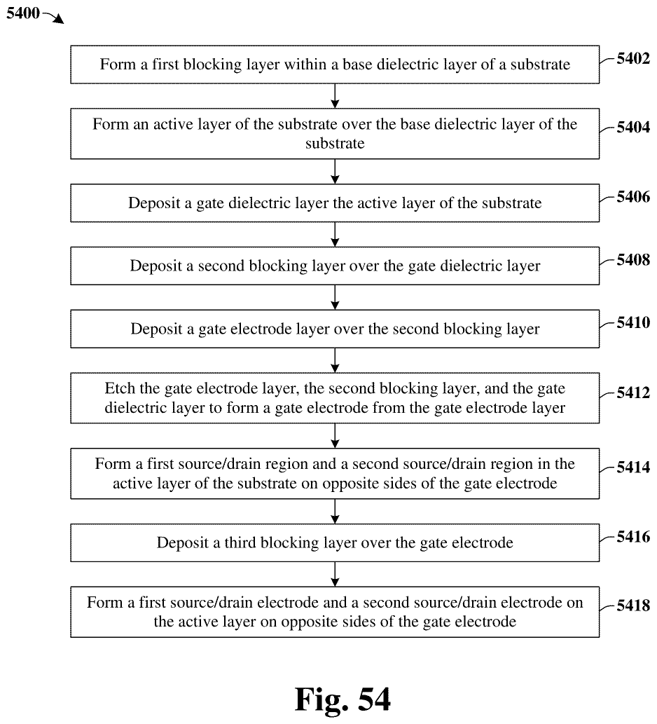

FIG. 54 illustrates a flow diagram of some embodiments of a method 5400 for forming a transistor device comprising blocking layers surrounding an active layer. While method 5400 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At block 5402, form a first blocking layer within a base dielectric layer of a substrate. FIG. 49 illustrates cross-sectional view 4900 of some embodiments corresponding to block 5402.

At block 5404, form an active layer of the substrate over the base dielectric layer of the substrate. FIG. 49 illustrates cross-sectional view 4900 of some embodiments corresponding to block 5404.

At block 5406, deposit a gate dielectric layer the active layer of the substrate. FIG. 49 illustrates cross-sectional view 4900 of some embodiments corresponding to block 5406.

At block 5408, deposit a second blocking layer over the gate dielectric layer. FIG. 49 illustrates cross-sectional view 4900 of some embodiments corresponding to block 5408.

At block 5410, deposit a gate electrode layer over the second blocking layer. FIG. 49 illustrates cross-sectional view 4900 of some embodiments corresponding to block 5410.

At block 5412, etch the gate electrode layer, the second blocking layer, and the gate dielectric layer to form a gate electrode from the gate electrode layer. FIG. 50 illustrates cross-sectional view 5000 of some embodiments corresponding to block 5412.

At block 5414, form a first source/drain region and a second source/drain region in the active layer of the substrate on opposite sides of the gate electrode. FIG. 51 illustrates cross-sectional view 5100 of some embodiments corresponding to block 5414.

At block 5416, deposit a third blocking layer over the gate electrode. FIG. 52 illustrates cross-sectional view 5200 of some embodiments corresponding to block 5416.

At block 5418, form a first source/drain electrode and a second source/drain electrode on the active layer on opposite sides of the gate electrode. FIG. 53 illustrates cross-sectional view 5300 of some embodiments corresponding to block 5418.

Thus, the present disclosure relates to an integrated chip comprising a transistor device, the transistor device comprising blocking layers surrounding an active layer to block harmful gasses from reaching the active layer.

Accordingly, in some embodiments, the present disclosure relates to an integrated chip including an active layer. A first source/drain electrode and a second source/drain electrode are on an upper surface of the active layer. A gate electrode is on a first side of the active layer and between the first source/drain electrode and the second source/drain electrode. A gate dielectric layer is between the gate electrode and the active layer. A first blocking layer is on a second side of the active layer, opposite the first side of the active layer, and spaced from the active layer. A second blocking layer is on the first side of the active layer, spaced from the active layer, and extends along the gate electrode.

In other embodiments, the present disclosure relates to an integrated chip including a first dielectric layer. A first blocking layer is over the first dielectric layer. A second dielectric layer is over the first blocking layer. An active layer is over the second dielectric layer. A first source/drain electrode and a second source/drain electrode are over the active layer. A gate electrode is over the active layer and between the first source/drain electrode and the second source/drain electrode. A gate dielectric layer between the gate electrode and the active layer. A second blocking layer is spaced over the active layer and extends along the gate electrode.

In yet other embodiments, the present disclosure relates to a method for forming an integrated chip. The method includes depositing a first blocking layer over a first dielectric layer. A second dielectric layer is deposited over the first blocking layer. An active layer is deposited over the second dielectric layer. A gate dielectric layer is deposited over the active layer. A gate electrode layer is deposited over the gate dielectric layer. A gate electrode is formed from the gate electrode layer. A first source/drain electrode and a second source/drain electrode are formed on the active layer and beside the gate electrode on opposite sides of the gate electrode. A second blocking layer is deposited over the active layer. The second blocking layer extends along the gate electrode.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated chip comprising:
an active layer;
a first source/drain electrode and a second source/drain electrode on an upper surface of the active layer;
a gate electrode on a first side of the active layer and between the first source/drain electrode and the second source/drain electrode;
a gate dielectric layer between the gate electrode and the active layer;
a first blocking layer on a second side of the active layer, opposite the first side of the active layer, and spaced from the active layer; and
a second blocking layer on the first side of the active layer, spaced from the active layer, and extending along the gate electrode.

2. The integrated chip of claim 1, wherein the second blocking layer is directly between the gate electrode and the gate dielectric layer.

3. The integrated chip of claim 2, wherein the second blocking layer extends along sidewalls of the gate electrode.

4. The integrated chip of claim 1, wherein the gate electrode is directly between the second blocking layer and the gate dielectric layer.

5. The integrated chip of claim 4, wherein the second blocking layer extends along sidewalls of the gate electrode, sidewalls of the gate dielectric layer, and the active layer.

6. The integrated chip of claim 4, further comprising:
a third blocking layer directly between the gate electrode and the gate dielectric layer.

7. The integrated chip of claim 1, wherein the gate electrode and the second blocking layer are over the active layer, wherein the first blocking layer is under the active layer, and wherein the active layer and the first blocking layer are spaced over a transistor device that is disposed along a semiconductor substrate.

8. The integrated chip of claim 1, wherein the gate electrode and the second blocking layer are under the active layer, wherein the first blocking layer, the first source/drain electrode, and the second source/drain electrode are over the active layer, and wherein the gate electrode and the second blocking layer are spaced over a transistor device that is disposed along a semiconductor substrate.

9. The integrated chip of claim 1, wherein the gate electrode is directly between the first and second source/drain electrodes and over a substrate, the substrate comprising the active layer, a base dielectric layer under the active layer, and a base semiconductor layer under the base dielectric layer, wherein the first blocking layer is within the base dielectric layer,
wherein the active layer has a first doping type, wherein a first source/drain region having a second doping type, different than the first doping type, is in the active layer directly under the first source/drain electrode, and wherein a second source/drain region having the second doping type is in the active layer directly under the second source/drain electrode.

10. An integrated chip comprising:
a first dielectric layer;
a first blocking layer over the first dielectric layer;
a second dielectric layer over the first blocking layer;
an active layer over the second dielectric layer;
a first source/drain electrode and a second source/drain electrode over the active layer;
a gate electrode over the active layer and between the first source/drain electrode and the second source/drain electrode;
a gate dielectric layer between the gate electrode and the active layer; and
a second blocking layer spaced over the active layer and extending along the gate electrode.

11. The integrated chip of claim 10, wherein the second blocking layer extends along a lower surface of the gate electrode and directly between the gate electrode and the gate dielectric layer, and wherein the first blocking layer comprises a first oxide and the second blocking layer comprises a second oxide different than the first oxide.

12. The integrated chip of claim 11, wherein the second blocking layer extends along a first sidewall of the gate electrode and directly between the gate electrode and the first source/drain electrode, and wherein the second blocking layer extends along a second sidewall of the gate electrode and directly between the gate electrode and the second source/drain electrode.

13. The integrated chip of claim 10, wherein the second blocking layer extends along an upper surface of the gate electrode, and wherein the gate electrode is directly between the second blocking layer and the active layer.

14. The integrated chip of claim 13, further comprising:
a third dielectric layer over the active layer and beside the gate electrode on opposite sides of the gate electrode, wherein the second blocking layer extends over the third dielectric layer on opposite sides of the gate electrode.

15. The integrated chip of claim 13, wherein the second blocking layer extends along sidewalls of the gate electrode, sidewalls of the gate dielectric layer, and an upper surface of the active layer.

16. The integrated chip of claim 15, further comprising:
a third blocking layer extending along a lower surface of the gate electrode and directly between the gate electrode and the gate dielectric layer, wherein the first blocking layer comprises a first oxide, the second blocking layer comprises a second oxide, and the third blocking layer comprises a third oxide different than the first oxide and the second oxide, and wherein the second blocking layer extends along sidewalls of the third blocking layer.

17. The integrated chip of claim 10, further comprising:
a semiconductor substrate spaced under the first dielectric layer;
a transistor device disposed along the semiconductor substrate; and
a plurality of conductive interconnects extending over the semiconductor substrate and coupling the transistor device to the first source/drain electrode, the second source/drain electrode, or the gate electrode.

18. A method for forming an integrated chip, the method comprising:
depositing a first blocking layer over a first dielectric layer;
depositing a second dielectric layer over the first blocking layer;
depositing an active layer over the second dielectric layer;
depositing a gate dielectric layer over the active layer;
depositing a gate electrode layer over the gate dielectric layer;
forming a gate electrode from the gate electrode layer;
forming a first source/drain electrode and a second source/drain electrode on the active layer and beside the gate electrode on opposite sides of the gate electrode; and
depositing a second blocking layer over the active layer, the second blocking layer extending along the gate electrode.

19. The method of claim 18, wherein the second blocking layer is deposited over the gate dielectric layer, and wherein the gate electrode layer is deposited over the second blocking layer.

20. The method of claim 18, wherein the second blocking layer is deposited over the gate electrode.
